(19) United States
(12) Patent Application Publication
(10) Pub. No.: US 2025/0029815 A1
(43) Pub. Date: Jan. 23, 2025

(54) METHOD AND DEVICE TO DISTRIBUTE GAS INTO A CONTAINER

(71) Applicant: ENTEGRIS, INC., Billerica, MA (US)

(72) Inventors: Mark V. Smith, Colorado Springs, CO (US); Matthew A. Fuller, Colorado Springs, CO (US); Shawn D. Eggum, Lonsdale, MN (US)

(21) Appl. No.: 18/778,788

(22) Filed: Jul. 19, 2024

Related U.S. Application Data
(63) Continuation-in-part of application No. 18/648,149, filed on Apr. 26, 2024.
(60) Provisional application No. 63/528,280, filed on Jul. 21, 2023.

(51) Int. Cl. H01J 37/32

(52) U.S. Cl. CPC H01J 37/32449; H01J 37/32844

(57) ABSTRACT

A method and purge gas assembly for supplying or distributing flow of purge gas into a substrate container is provided. The purge gas assembly includes a gas distributor comprising at least one outlet and a purge module comprising an inlet for receiving a flow of purge gas, a check valve, and an outlet. A combination of the gas distributor and purge module form a chamber. The chamber is configured to supply the purge gas to the at least one outlet of the gas distributor.

### FIELD

This disclosure is directed to methods and systems for controlling or distributing gas into a container. More specifically, this disclosure relates to a purge flow distribution system for controlling or distributing flow of purge gas into a substrate container and modules thereof.

### BACKGROUND

Substrates in the form of wafers can be processed to form semiconductor devices. The wafer substrates, or simply substrates, undergo a series of process steps. Exemplary process steps can include, but are not limited to, material layer deposition, doping, etching, or chemically or physically reacting material(s) of the substrate. A substrate container is used to store and transport the in-process wafers between process steps within the fabrication facility. During some process steps, the substrates are processed by processing equipment within a clean environment (e.g., a clean room). During processing, gasses must be introduced and removed from the substrate container such as a front opening unified pods (FOUP), for example during purge processes, thus requiring that the FOUP have one or more locations at which purge gas may enter or leave the FOUP. Substrates can be transferred from the substrate container to the processing tool through an equipment front end module (EFEM). The EFEM generally includes a load port for receiving the substrate container, a transfer unit, a frame or “mini-environment”, and a fan filter unit used to generate gas flow within the EFEM.

In use, the substrate container can be docked on a load port. Next, the door is disengaged from the substrate container which permits the transfer unit housed within the EFEM to access the substrates contained within the substrate container for processing. A flow of gas introduced by the fan filter unit flows through the EFEM in a direction from a top of the EFEM to a bottom of the EFEM. When the front opening of the substrate container interfaces with the load port opening of the EFEM some of the gas flowing through the EFEM and across the load port opening may be inadvertently directed into the interior of the container, potentially interfering with the purging capabilities of the substrate container by temporarily causing an increase in the relative humidity or oxygen levels within the microenvironment of substrate container, which can be undesirable.

Purge gases can be used to remove or prevent entry of contaminants to protect the substrates and improve yield for the processing of those substrates, e.g., wafers. The purge gases are typically provided by diffusers, for example, diffuser towers, provided for each port configured to receive purge gas, providing a standard flow rate based on the supply of purge gas to the port, which are installed in the substrate container by placing the diffuser into the container and attaching the diffuser to a fitting provided inside the wafer container. Purge assemblies can direct the received flow of purge gas to a diffuser, to be provided at a particular location within the wafer container.

Containers used in substrate processing can be purged, using a suitable purge gas to drive out moist air or other potential contaminants to protect the wafers and improve yield for the processing of those substrates. The purge can be provided to the interior of the container using a purge assembly. Purge assemblies for substrate containers such as front-opening unified pods (FOUPs) typically include multiple discrete components including a grommet, a valve such as a check valve, and various sealing members. Diffusers can be installed to the purge assembly once it is installed in the substrate container by placing the diffuser into the container and attaching the diffuser to a fitting provided inside the substrate container. Purge assemblies can direct the received flow of purge gas to a diffuser, to be provided at a particular location within the substrate container. Filters are typically retained by fastening them into place in a filter element that is then included in the purge assembly. The filters are typically circular in shape.

### SUMMARY

This disclosure is directed to methods and systems for controlling or distributing purge for substrate containers, e.g., wafer or reticle carrying containers, such as FOUPs or pods (e.g., reticle pods) that are used, for example, in semiconductor manufacturing. More specifically, this disclosure relates to a purge flow distribution system for controlling or distributing flow of purge gas into a substrate container and modules thereof.

A purge module can be configured to filter a received flow and direct a first portion of the filtered received flow to a diffuser, and a second portion of the filtered received flow to another space, which can allow this second portion to be directed to another structure for introduction into the substrate container, allowing purge operations in the substrate container to be improved through additional points of introduction of the purge gas.

The purge module can be configured such that the diffuser can be attached prior to attachment to the substrate container, and the substrate container and purge module can be configured such that the assembled diffuser and purge module can be inserted into an interior space of the shell of the substrate container from an exterior of said shell the substrate container to install the purge module and diffuser into the substrate container. This can allow the insertion of the purge module and diffuser without requiring any operations be performed inside the shell of the substrate container. This can reduce the likelihood of installation errors and/or reduce particle generation or addition of contaminants within the shell of the substrate container. This can in turn reduce the loss of wafers and improve yields from processes using substrate containers including such purge modules and diffusers.

In an embodiment, a filter with an opening can be used, allowing some components of the purge module to extend through the filter with reduced impact on an overall length of the purge module. This can allow, for example, a larger check valve to be used, allowing greater purge flows without causing issues such as lifting, pressure spikes, or the like, and thus improving purge effectiveness.

In an embodiment, a method for distributing flow of purge gas into a substrate container is provided. The method includes receiving a stream of purge gas at an inlet of a purge module and supplying the purge gas from an outlet of the purge module into a chamber formed by a combination of the purge module and a gas distributor of a purge gas assembly, the gas distributor having at least one outlet. The method further includes dividing, in the chamber, the purge gas into at least a first flow path to supply the purge gas to the at least one outlet of the gas distributor.

In another embodiment, a purge gas assembly for supplying purge gas to a substrate container is provided. The purge gas assembly includes a gas distributor comprising at least one outlet; a purge module including an inlet for receiving a flow of the purge gas, a check valve, and an outlet. A combination of the gas distributor and the purge module form a chamber, and the chamber is configured to supply the purge gas to the at least one outlet of the gas distributor.

In yet another embodiment, a method for assembling a substrate container having a gas distribution device is provided. The method including attaching a purge gas assembly to a bottom wall of the substrate container, in which the purge gas assembly includes a gas distributor that has at least one outlet; assembling a purge module including an inlet for receiving a flow of purge gas, a check valve, and an outlet; and inserting the purge module into the gas distributor to form a chamber such that the chamber is configured to supply the purge gas to the at least one outlet, in which the method is performed externally of the substrate container.

As such, the substrate container having the purge gas assembly or the purge gas assembly, as discussed herein, have at least the following benefits:

A structure that is configured to deliver purge gas to front gas distributing devices, such as, manifolds or diffusers, from existing rear purge gas inlet locations, in which the purge gas is delivered through or along the substrate container shell into the front gas distributing devices.

A structure that is configured to control or distribute purge gas from the rear purge gas inlet locations to the front of the substrate container by dividing or diverting portions of the purge gas such that the amount of purge gas can be adjusted for optimal performance.

A method to transport or control the flow of the purge gas from the inlet location(s) to the gas distributing devices inside the substrate container, and, especially, from a rear purge module to the front gas distributing devices.

In an embodiment, a purge module includes a grommet, a check valve at least partially received in the grommet, and a module body. The module body includes a cavity configured to accommodate the grommet and the check valve. The module body defines one or more passages from the cavity. The purge module further includes a filter and a filter retainer. The filter retainer and the module body are configured to contain the filter. The purge module also includes a diffuser retainer configured to support a diffuser. The diffuser retainer includes a diffuser inlet. The filter retainer and the diffuser retainer are configured such that a first portion of a flow of gas through the filter enters the diffuser inlet and a second portion of the flow of gas through the filter passes through one or more apertures defined by one or both of the filter retainer and the diffuser retainer.

In an embodiment, the purge module further includes the diffuser. In an embodiment, the diffuser is entirely within a perimeter of the module body in plan view.

In an embodiment, the module body includes a projection extending from a surface, the surface including an end of at least one of the one or more passages. In an embodiment, a portion of the cavity is defined by the projection, and a portion of the check valve extends into said portion of the cavity.

In an embodiment, the filter includes an opening defined by an inner perimeter, the opening configured to receive the projection. In an embodiment, the filter retainer and the module body are configured such that when the filter retainer and the module body are snap-fit together, the filter retainer and the module body clamp the filter along the entire inner perimeter and along an entire outer perimeter of the filter.

In an embodiment, the module body includes a groove provided on an outer surface of the module body, and the purge module further comprises a lip seal or an O-ring disposed in said groove.

In an embodiment, the purge module includes a module retainer, the module retainer configured to engage with one or more features of a substrate container.

In an embodiment, the module body and the filter retainer are configured to be joined by a snap-fit.

In an embodiment, a method of directing purge gas into a substrate container includes receiving the purge gas at a grommet of a purge module, directing the purge gas through a check valve into a cavity defined in a module body of the purge module, directing the purge gas from the cavity to a filter through one or more passages in the module body, directing a first portion of the purge gas from the filter into a diffuser, the diffuser retained in a diffuser retainer included in the purge module, and directing a second portion of the purge gas out of the purge module through one or more apertures defined by one or both of a filter retainer and the diffuser retainer.

In an embodiment, the second portion of the purge gas is directed into a chamber surrounding the purge module, and the method further includes directing the second portion of the purge gas from the chamber to a second diffuser.

In an embodiment, a flow rate of the purge gas received at the grommet is in a range from 400 standard L/minute or less.

In an embodiment, a method includes assembling a purge module. Assembling the purge module includes attaching a check valve to a grommet, inserting the grommet into a module body, clamping a filter between the module body and a filter retainer, and attaching a diffuser retainer to the filter retainer. The diffuser retainer includes a diffuser inlet.

In an embodiment, the filter retainer and the diffuser retainer are configured such that a first portion of a flow of gas through the filter enters the diffuser inlet and a second portion of the flow of gas through the filter passes through one or more apertures defined by one or both of the filter retainer and the diffuser retainer.

In an embodiment, the method further includes attaching a diffuser to the diffuser retainer. In an embodiment, the method further includes inserting the diffuser through an aperture provided on a substrate container from an exterior of the substrate container and inserting the purge module into the aperture such that at least a portion of the purge module is received within the aperture. In an embodiment, the aperture is formed by a shell and a bottom plate of the substrate container.

In an embodiment, the method further includes attaching a locking ring to the module body such that the locking ring can be rotated independently of the module body. In an embodiment, the method further includes inserting the purge module into an aperture provided on the substrate container from an exterior of the substrate container such that at least a portion of the purge module is received within the aperture, and rotating the locking ring such that the locking ring engages one or more engagement features provided at the aperture.

In an embodiment, a purge module includes a grommet, a check valve at least partially received in the grommet, and a module body. The module body includes a cavity configured to accommodate the grommet and the check valve. The module body defines one or more passages from the cavity. The purge module further includes a filter and a filter retainer. The filter retainer and the module body are configured to contain the filter. The module body includes a projection extending from a surface and the surface includes an end of at least one of the one or more passages. The filter includes an opening defined by an inner perimeter, the opening configured to receive the projection.

In an embodiment, a portion of the cavity is defined by the projection, and a portion of the check valve extends into said portion of the cavity.

In an embodiment, the filter retainer and the module body are configured such that when the filter retainer and the module body are snap-fit together, the filter retainer and the module body clamp the filter along the entire inner perimeter and along an entire outer perimeter of the filter.

In an embodiment, the purge module further includes a diffuser retainer configured to support a diffuser, the diffuser retainer including a diffuser inlet.

In an embodiment, the filter retainer and the diffuser retainer are configured such that a first portion of a flow of gas through the filter enters the diffuser inlet and a second portion of the flow of gas through the filter passes through one or more apertures defined by one or both of the filter retainer and the diffuser retainer.

In an embodiment, the purge module further includes the diffuser. In an embodiment, the diffuser is entirely within a perimeter of the module body in plan view.

In an embodiment, the module body includes a groove provided on an outer surface of the module body, and the purge module further comprises a lip seal or an O-ring disposed in said groove.

In an embodiment, the purge module includes a module retainer, the module retainer configured to engage with one or more features of a substrate container.

In an embodiment, the module body and the filter retainer are configured to be joined by a snap-fit.

In an embodiment, a method includes assembling a purge module. Assembling the purge module includes attaching a check valve to a grommet and inserting the grommet into a module body. The module body includes a surface having a projection. The method further includes positioning a filter having an opening such that the projection extends through the opening and attaching a filter retainer to the module body such that the filter retainer and the module body clamp the filter at an outer perimeter of the filter and at an inner perimeter of the filter. The inner perimeter defines the opening.

In an embodiment, the method further includes attaching a diffuser retainer to the filter retainer, wherein the diffuser retainer includes a diffuser inlet. In an embodiment, the filter retainer and the diffuser retainer are configured such that a first portion of a flow of gas through the filter enters the diffuser inlet and a second portion of the flow of gas through the filter passes through one or more apertures defined by one or both of the filter retainer and the diffuser retainer. In an embodiment, the method further includes attaching the diffuser to the diffuser retainer. In an embodiment, the method further includes inserting the diffuser through an aperture provided on a substrate container from an exterior of the substrate container and inserting the purge module into the aperture such that at least a portion of the purge module is received within the aperture.

In an embodiment, the method further includes attaching a locking ring to the module body such that the locking ring can be rotated independently of the module body. In an embodiment, the method further includes inserting the purge module into an aperture provided on a substrate container from an exterior of the substrate container such that at least a portion of the purge module is received within the aperture, and rotating the locking ring such that the locking ring engages one or more engagement features provided at the aperture.

In an embodiment, the filter retainer and the module body clamp the filter over an entirety of the outer perimeter of the filter and over an entirety of the inner perimeter of the filter.

In an embodiment, the filter retainer and the module body are joined by a snap-fit.

In an embodiment, the module body defines a cavity, a portion of the cavity is defined by the projection, and a portion of the check valve extends into said portion of the cavity.

In an embodiment, a purge assembly for a substrate container includes a housing and a purge module defining a chamber. The purge module includes a grommet, a check valve at least partially received in the grommet, and a module body. The module body includes a cavity configured to accommodate the grommet and the check valve. The module body defines one or more passages from the cavity. The purge module further includes a filter and a filter retainer. The filter retainer and the module body are configured to contain the filter. The purge module is configured to receive a flow of purge gas, direct the flow of purge gas through the check valve to the filter, and allow at least a portion of the flow of purge gas to pass from the purge module into the chamber.

In an embodiment, the purge module further includes a diffuser configured to extend from the housing. In an embodiment, the diffuser is retained in the housing. In an embodiment, the purge module contacts the diffuser such that the diffuser is retained in an aperture provided in the housing. In an embodiment, the purge module further includes a diffuser retainer further configured to support the diffuser.

### DRAWINGS

FIG. 1 shows an exploded view of a substrate container having a purge gas assembly, according to an embodiment.

FIGS. 2A and 2B illustrate an exploded view of an assembly of a purge gas assembly, according to an embodiment.

FIG. 3 shows a sectional view of a purge gas assembly and a purge module for receiving purge gas, according to an embodiment.

FIGS. 4A, 4B, 4C show a purge gas assembly attached to a carrier plate, according to an embodiment.

FIG. 5 shows a flowchart for controlling a flow of purge gas through the purge gas assembly, according to an embodiment.

FIG. 6 shows a flowchart for assembling a substrate container having a purge gas assembly, according to an embodiment.

FIG. 7A shows an exploded view of a purge module according to an embodiment.

FIG. 7B shows an exploded view of a purge module according to an embodiment.

FIG. 8 shows a sectional view of a purge module according to an embodiment.

FIG. 9A shows a sectional view of a purge module at an inner circumference of a filter according to an embodiment.

FIG. 9B shows a sectional view of the purge module of FIG. 9A at an outer circumference of a filter according to an embodiment.

FIG. 10 shows a flowchart of a method for assembling a purge module according to an embodiment.

FIG. 11 shows a flowchart of flow of purge gas through the purge module according to an embodiment.

### DETAILED DESCRIPTION

While the terms “front” and “rear” and “right” and “left” are used herein for describing various elements, the elements are not limited by these terms. Rather, the terms are only used to distinguish one element from another. Instead, the terms are interpreted broadly to include any positional relationship between the elements including, the front, the back, the sides, the top, the bottom, or any combination thereof without departing from the scope of the present disclosure.

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The following detailed description should be read with reference to the drawings in which similar elements in different drawings are numbered the same. The detailed description and the drawings, which are not necessarily to scale, depict illustrative embodiments and are not intended to limit the scope of the invention. The illustrative embodiments depicted are intended only as exemplary. Selected features of any illustrative embodiment may be incorporated into an additional embodiment unless clearly stated to the contrary.

This disclosure is directed to methods and systems for controlling or distributing purge gas for substrate containers, e.g., wafer or reticle carrying containers, such as, front opening unified pods (FOUPs) or pods (e.g., reticle pods) that are used, for example, in semiconductor manufacturing. The substrate container is a container for carrying substrates during different processing steps, in which the substrates can be in the form of wafers, reticles, panels, or trays that can be processed to form semiconductor devices. The substrate container is accessed through a front opening of the substrate container. More specifically, this disclosure relates to a purge gas assembly for controlling or distributing flow of purge gas into a substrate container, in which the purge gas assembly is configured to supply a flow of purge gas into an interior space of the substrate container by dividing the stream of purge gas, and preferably into a first flow path to supply a first gas distributing device and a second flow path to supply a second gas distributing device. In some embodiments, the purge gas assembly can be configured to prevent ingress of gas into the front opening of the substrate container while open or as an outlet to facilitate the exhaustion of purge gas from the substrate container when the substrate container is closed.

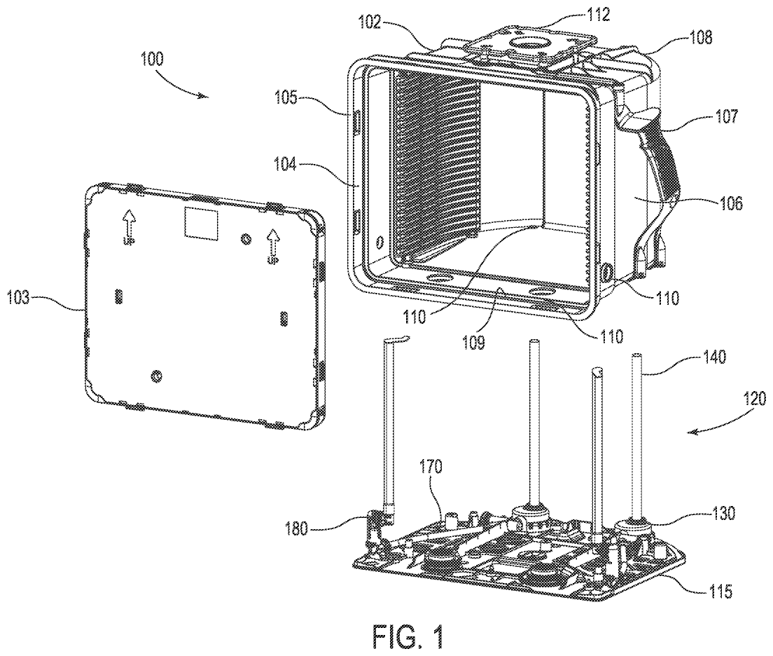

FIG. 1 shows an exploded view of a substrate container 100, carrier (or conveyor) plate 115, and purge gas assembly 120 for supplying purge gas to the substrate container 100, according to an embodiment. In an embodiment, the purge gas assembly 120 can be configured to filter a received flow of purge gas and direct a first portion of the purge gas to a first gas distributing device, and a second portion of the purge gas to at least a second gas distributing device to allow purging operations in the substrate container to be improved through additional points of introduction of the purge gas, as discussed further below. In some embodiments, the components of the purge gas assembly 120 can include one or more of purge module(s), the gas distributing device(s), control valve(s), piping, etc. In some embodiments, some of the components, such as the purge module, can be assembled or attached separately from the purge gas assembly 120, e.g., modular components. As such, at least portions of the purge gas assembly 120 can be pre-assembled on the carrier plate 115 and attached to the substrate container 100. In some embodiments, the purge module can be assembled or attached to the purge gas assembly 120 after the purge gas assembly 120 has been attached to the substrate container 100 such that the purge module can be installed into the substrate container 100 without requiring (or minimally requiring) any operations be performed inside the container body 102 of the substrate container 100. By being able to install some components of the purge gas assembly 120, and specifically, the purge module, from outside the substrate container 100, such installation can reduce the likelihood of installation errors or reduce particle generation or addition of contaminants within the container body or shell of the substrate container. This can in turn reduce the loss of substrates, such as wafers, and improve yields from processes using substrate containers that include the purge gas assembly(s) or gas distributing device(s). In some embodiments, the purge gas assembly 120 can be configured such that the purge gas assembly 120 includes any of its components, including any gas distributing devices, such as, a diffuser or manifold, attached together prior to attachment to the substrate container 100. In other embodiments, the different components of the purge gas assembly 120 can be modular in that the different components can be removed or modified, as necessary.

Referring back to FIG. 1, substrate container 100 includes container body 102 and front door 103. Substrate container 100 is a container configured to accommodate one or more substrates for transport, storage, or processing of the substrates. The substrates contained in substrate container 100 can be, for example, semiconductor substrates such as wafers. The substrate container 100 can be any suitable container for the substrate, such as a front opening uniform pod (FOUP). In an embodiment, the substrate container 100 can be a container for a reticle, such as a reticle pod. In such an embodiment, the container body 102 can be included as at least part of an outer pod configured to contain an inner pod.

Container body 102 defines an interior space 104 configured to contain one or more substrates, such as wafers, for processing. A front opening, e.g., via removal of the front door 103, can allow the substrates to be inserted into or removed from container body 102. The container body 102 includes a first side wall 105, a second side wall 106, a rear wall 107, and a top wall 108, and a bottom wall 109. The substrate container 100 can include on the bottom wall 109 or the first side wall 105 and second side wall 106, a plurality of inlet purge port(s) 110 or outlet purge port(s) 110 corresponding to inlet(s) or outlet(s) of the substrate container 100. The plurality of inlet purge port(s) 110 (and outlet purge ports) can be connected to a purge gas assembly 120, as further discussed below. At least one outlet port 110 can be provided for discharging gas in the interior space 104 out of the substrate container 100 and can be disposed in the bottom wall 109. It is appreciated that the inlet purge port(s) 110 or outlet purge port(s) 110 can also be provided in different positions along the container body 102, e.g., in the rear wall 107.

The substrate container 100 can also include a top automation feature, such as, an equipment hookup 112 on the top wall of the container body 102. In an embodiment, the equipment hookup 112 can allow a standard automated attachment (not shown) for moving the substrate container 100, such as, but not limited to an automated arm, to be connected to the substrate container 100. For example, the automated arm may be used to move the substrate container 100 between different processing equipment. In an embodiment, the substrate container 100 may include one or more handles to allow a user (e.g., a technician, etc.) to manually move the substrate container 100.

The carrier plate 115 can provide a base that the container body 102 can be attached to or be a base that the purge gas assembly 120 can be attached to. The carrier plate 115 can be a bottom plate with an automation interface that is configured to attach to a conveyor system for the processing of the substrate or assembly of the substrate container 100.

Purge gas assembly 120 can be attached to a top surface of the carrier plate 115 or integrally formed therewith. In an embodiment, a portion of the purge gas assembly 120 can be located within the container body 102. In an embodiment, the purge gas assembly 120 can be located adjacent to the container body 102. In an embodiment, the purge gas assembly 120 can be at least partially disposed between the container body 102 and the carrier plate 115. While the purge gas assembly 120 is discussed herein as being attached to the carrier plate 115, such disclosure is not intended to be limiting. In an embodiment, the purge gas assembly 120 can be attached to the bottom wall of the substrate container 102 or provided between the substrate container 100 and the carrier plate 115.

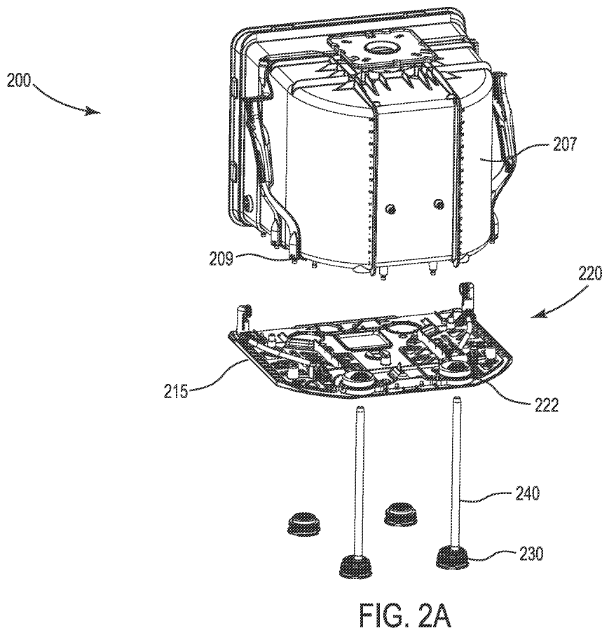

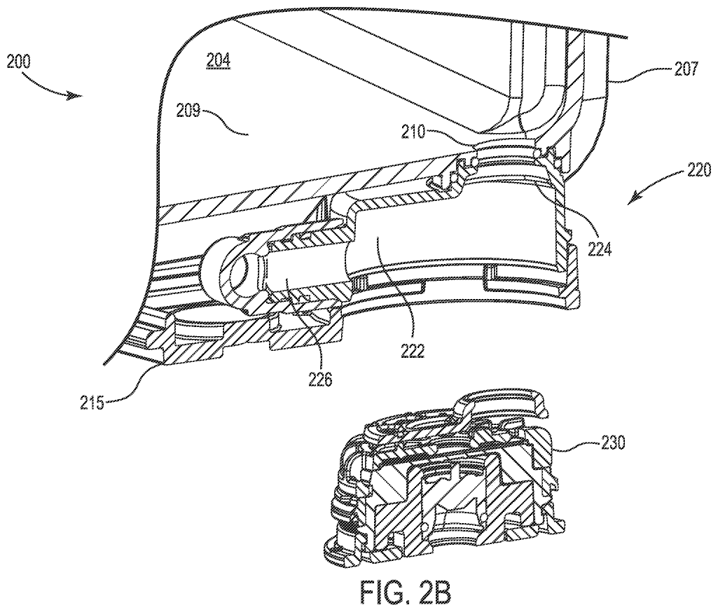

The purge gas assembly 120 is configured to distribute purge gas to one or more gas distribution devices. The purge flows can be of any suitable gas that does not contaminate the environment within container body 102. Non-limiting examples of the purge flow gas can be nitrogen, clean dry air (CDA), or the like. The purge gas assembly 120, as discussed in further detail below, includes a gas distributor 130 configured to receive a purge module such as purge module 230 described below and shown in FIG. 2. The purge module 230 can have an inlet for receiving a flow of purge gas, a check valve for regulating a flow direction of the purge gas, and an outlet for supplying the purge gas. The purge module 230 can be configured such that a first gas distributing device 140, e.g., a diffuser or manifold, can be attached to the purge module 130. In some embodiments, the purge gas assembly 120 can include at least two purge modules 230 for providing purge gas to first and second sides of the substrate container 100, in which each of the purge modules 230 is configured to supply purge gas to one or more of a rear gas distributing device for a rear portion of the substrate container 100, a front gas distributing device 180 for a front portion of the substrate container 100, or other purge port(s) on the substrate container 100. In some embodiments, the purge gas assembly 120 can be configured such that the first gas distributing device(s) 140 can be attached directly to the purge gas assembly 120, or a portion thereof, for providing the purge gas inside the substrate container 100.

In some embodiments, the purge gas assembly 120 can also include a control valve connected to the purge module 130, in which the control valve is configured to control the distribution of the flow of purge gas, and tubing 170 for connecting the purge module 130 to at least one front gas distributing device for distributing purge gas to a front of the substrate container 100. It is appreciated that while the purge gas assembly 120 is discussed herein as including a control valve, such disclosure is not limiting, since other devices can be used to control or regulate the flow of purge gas through the purge gas assembly 120 to the front gas distributing device. For example, in some embodiments, an orifice, spring loaded diverter, or tubing or piping/pipes that have smaller or larger cross-sectional areas can be used to regulate the flow of purge gas.

FIGS. 2A and 2B are an exploded view and a partial cross-sectional view of an example embodiment of an assembly of a substrate container 200 having a purge gas assembly 220 which can have the same or similar features as the purge gas assembly 120 of FIG. 1. The substrate container 200 has at least an interior space 204, a rear wall 207, and a bottom wall 209, in which the bottom wall 209 includes at least an input purge port 210 for receiving a gas distributing device, such as, a diffuser or manifold 240. At least some of the components of purge gas assembly 220 can be attached to a top surface of a carrier plate 215 and includes a purge module 230.

The purge gas assembly 220 includes a gas distributor 222 having one or more outlets, in which the gas distributor 222 is configured to receive the purge module 230. In an embodiment, the gas distributor can be a plenum, manifold, or other gas distributing structure and can have a first outlet that defines a first opening 224 for directing a first flow path of a first portion of a purge gas for distributing to the rear portion of the substrate container 200, e.g., via input purge port 210, and a second outlet that defines a second opening 226 for directing a second flow path of a second portion of the purge gas for distributing the purge gas to a front portion (not shown) of the substrate container 200. When the purge module 230 is inserted into the gas distributor 222, the combination of the purge module 230 and the gas distributor 222 form a chamber that is fluidly sealed such that the combination of the purge module 230 and the gas distributor 222 form a plenum, manifold, or other gas distributing device in which the purge gas from the outlet of the purge module 230 is received in an enclosed space or volume of the chamber for being divided into the first flow path to the first outlet of the gas distributor and the second flow path to the second outlet of the gas distributor.

In an embodiment, the combination of the gas distributor 222 and the purge module 230 is configured such that a second portion of the flow of purge gas received via an inlet of the purge module 230 is received in the chamber and directed to the second opening 226 via an outlet of the purge module 230 and a first portion of the flow of purge gas is divided or diverted from the outlet of the purge module 230, e.g., a diffuser retainer or diffuser inlet, to the rear diffuser 240 via the first opening 224 to distribute the purge gas in the rear portion of the substrate container 200 via input purge port 210. In an embodiment, a pressurization of the chamber can be controlled by a control valve connected to the second outlet of the gas distributor 222 at the second opening 226. For example, by adjusting or controlling the control valve to regulate or distribute a flow of gas in the second flow path, some of the purge gas flows through the control valve and some through the first opening 224, e.g., the rear diffuser 240. As such, the purge gas is divided or distributed within the chamber for supplying purge gas, for example, to a front diffuser via second opening 226 and the rear diffuser via first opening 224 for distributing the purge gas into the interior space 204. While not intending to be limiting, the at least one gas distributing device is discussed as being a rear gas distributing device or diffuser and a front gas distributing device or diffuser. It is appreciated that more than two gas distributing devices can be used at various locations of the substrate container 200 or portions of the purge gas assembly plugged or capped, e.g., not including a gas distributing device for distributing purge gas into the substrate container 200.

Referring back to FIGS. 2A and 2B, an assembly of the substrate container 200 having the purge gas assembly 220 is discussed below. As discussed above, in some embodiments, the purge gas assembly 220 or components thereof can be pre-assembled. For example, in an embodiment, the purge gas assembly 220 is attached to the top surface of the carrier plate 215 in which some of the components, such as, tubing, control valve, gas distributor 222, or the like are assembled on the top surface of the carrier plate 215. The carrier plate 215 (or the purge gas assembly 220 alone) can be attached to the bottom wall 209 of the substrate container 200. It is appreciated that the attachment of the carrier plate 215 to the substrate container 200 can be securely fixed, e.g., using tabs, screws, or other fastening devices, and are able to be disassembled or removably attachable, as necessary. After the carrier plate 215 having the purge gas assembly 220 is attached to the substrate container 200, e.g., made integral, in which the carrier plate 215 is formed as the bottom plate of the substrate container 200, the purge module 230 is inserted into the purge gas assembly 220 and specifically into the gas distributor 222. As such, the combination of the purge module 230 and the gas distributor 222 form a chamber for directing at least one first flow path to the outlet of the gas distributor 222. In an embodiment, the purge module 230 can include a gas distributing device, e.g., a diffuser 240, in which the diffuser 240 can be inserted into the interior space 204 of the substrate container 200 via the input purge port 210. At least in view of the construction of the purge gas assembly 220 and the purge module 230, it is appreciated that the purge module 230 is modular in that the purge module 230 can be removed and replaced in a way such that the purge module 230 can be installed into the purge gas assembly 220 or the substrate container 200 without requiring (or minimally requiring) any operations be performed inside the substrate container 200. While the gas distributor 222 and chamber have been discussed above with respect to at least two outlets or openings, such disclosure is not intended to be limiting. For example, in an embodiment, the gas distributor 222 and chamber can have only one outlet for receiving the purge gas from the outlet of the purge module 230 in the volume or space formed between the gas distributor 222 and the purge module 230. While the purge module 230 for receiving the inlet purge gas has been discussed as being rear purge module(s), it is understood that the purge module 230 can be positioned at other locations, e.g., front, middle or side, depending on the substrate processing system and substrate container. Furthermore, while the gas distributing devices have been discussed herein as diffusers or manifolds, it is understood that other gas distributing devices can be included. For example, the gas distributing device can be diffusers, manifolds, membranes, portions having slits or nozzles or is made of porous material, elbows, or flow diverters, or similar structures that is able to direct the purge gas into the interior of the substrate container, and combinations of the same.

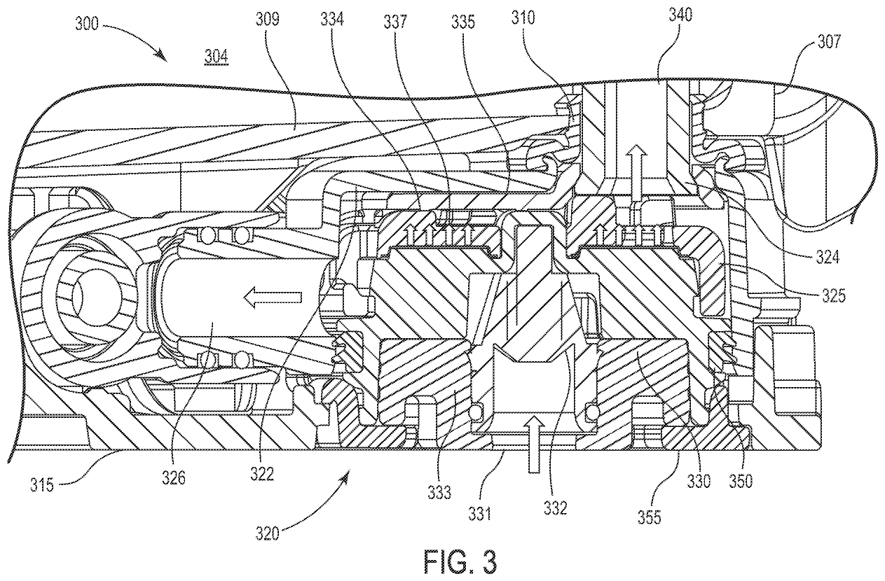

FIG. 3 is a cross-sectional view of an example embodiment of a rear portion of a substrate container 300 having a purge gas assembly 320, which can have the same or similar features as the purge gas assembly 120 of FIG. 1 or 220 of FIG. 2. The substrate container 300 has an interior space 304, a rear wall 307, and a bottom wall 309, in which the bottom wall 309 includes inlet purge port 310 for receiving a gas distributing device, such as, a diffuser 340. The purge gas assembly 320 is attached to a top surface of a carrier plate 315 and includes a purge module 330 and gas distributor 322 which in combination form a chamber for receiving the purge gas from the purge module 330.

The combination of the gas distributor 322 and the purge module 330 includes a first outlet defining a first opening 324 for directing a first flow path of a first portion of a purge gas for distributing to the rear portion of the substrate container 300, e.g., via inlet purge port 310 and/or rear diffuser 340, and a second outlet defining a second opening 326 for directing a second flow path of a second portion of the purge gas for distributing the purge gas to a front portion (not shown) of the substrate container 300. In an embodiment, the purge module 330 is inserted into the gas distributor 322 and the diffuser 340 is attached to the purge module 330 and inserted into the rear portion of the substrate container 300 via inlet purge port 310 to form a sealing arrangement. In an embodiment, sealing ring 350 can be provided around an outer surface of the purge module 330 such that at least an outlet of the purge module 330 is fluidly sealed by the gas distributor 322 and sealing ring 350. As such, the purge gas exiting the outlet of the purge module 330 is divided within the chamber in which a first portion of the purge gas is directed to the first opening 324 and a second portion of the purge gas is directed to the second opening 326, e.g., pressurization controlled by a control valve attached to the second outlet of the gas distributor 322. The sealing ring 350 can be a lip seal, an O-ring, sealing gasket, or other compressible mechanical gasket material, for example, polymeric or elastomeric material. In some embodiments, the purge module 330 can be sealed entirely within the gas distributor 322 and in some embodiments, only the outlet of the purge module 330 is sealed by the gas distributor 322. While the chamber as discussed herein has been described as a space or volume between the gas distributor 322 and the purge module 330, it is understood that such disclosure is not intended to be limiting. For example, in some embodiments, the chamber can be formed in other structures, e.g., a chamber body, the bottom wall of the substrate container or portion of the bottom plate, to form a sealing arrangement with the purge module 330 or other purge gas distributor, such that the purge gas from an outlet of the purge module 330 or other purge gas distributor can be divided or distributed to one or more flow paths.

In an embodiment, the purge module 330 can be retained to the purge gas assembly 320 using a module retainer 355. The module retainer 355 can be configured to retain the purge module 330 to the carrier plate 315, e.g., via hooks or tabs or screw fitting, or to the purge gas assembly 320. The module retainer 355 can allow the separate installation or replacement of the purge module 330 or the diffuser 340 to the substrate container 300 apart from the purge gas assembly 320. As such, the purge module 330 can be a stand-alone unit that can be assembled on the substrate container 300 at a later time.

In an embodiment, the purge module 330 can include an inlet 331, a check valve 332 for regulating a flow direction of the purge gas, a grommet 333, and an outlet 334. At the inlet 331, a stream of purge gas can be received from a purge gas supply system. The purge gas supply system delivers purge gas which may generally be an inert gas. The purge gas can include, for example, but is not limited to, one or more of nitrogen, clean dry air (CDA), and extra clean dry air (xCDA). The check valve 332 is received in the grommet 333 and configured to allow the flow of purge gas in only one direction from the inlet 331 to the outlet 334 through the grommet 333. The grommet 333 defines one or more passages or passageways from the inlet 331 for passing the purge gas to the check valve 332. The purge module 330 can further include a filter disposed before or after the outlet 334, a filter retainer for retaining the filter on the purge module 330, a diffuser retainer 335 configured to support the diffuser 340, and the diffuser 340 attached to the purge module 330 or the purge gas assembly 320. The filter retainer and the diffuser retainer can be configured such that the purge gas exiting the outlet 334 is divided or distributed such that a first portion of the flow of purge gas through the filter enters the first opening 324 by at least being partially connected to the diffuser 340 and a second portion of the flow of purge gas through the filter passes through one or more apertures 337 defined by one or both of the filter retainer and the diffuser retainer and enters at least the chamber 322.

As such, in the embodiments as discussed herein, the purge gas assembly having the chamber formed by the combination of the gas distributor and the purge module allows for multiple openings for the purge gas to exit to provide one or more flow paths for supply of purge gas to the interior space of the substrate container 300. That is, the purge gas can flow vertically through the first opening into the rear diffuser as well as, in some embodiments, horizontally through the second opening to the front diffusers to allow for multiple diffusion/purge locations from one load port inlet. Furthermore, since the purge gas is delivered from the outlet of the purge module, which is after the filter, the purge gas is filtered.

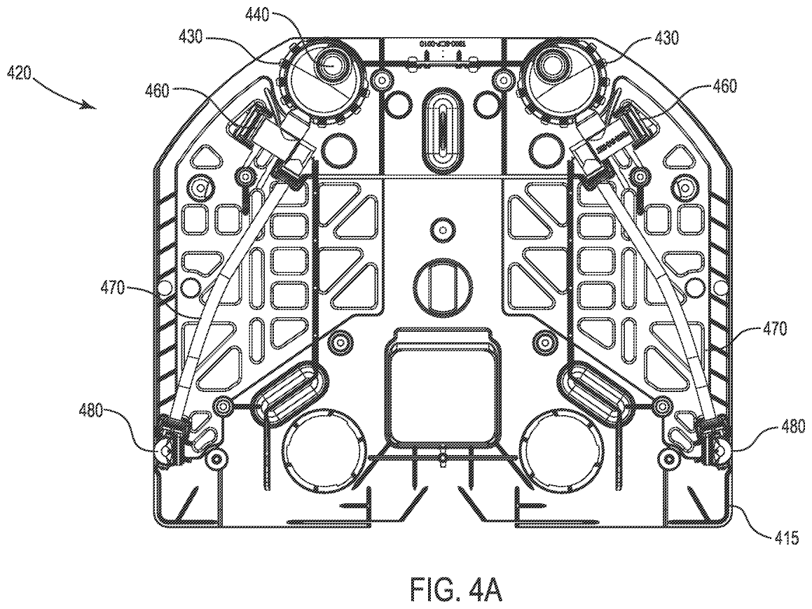

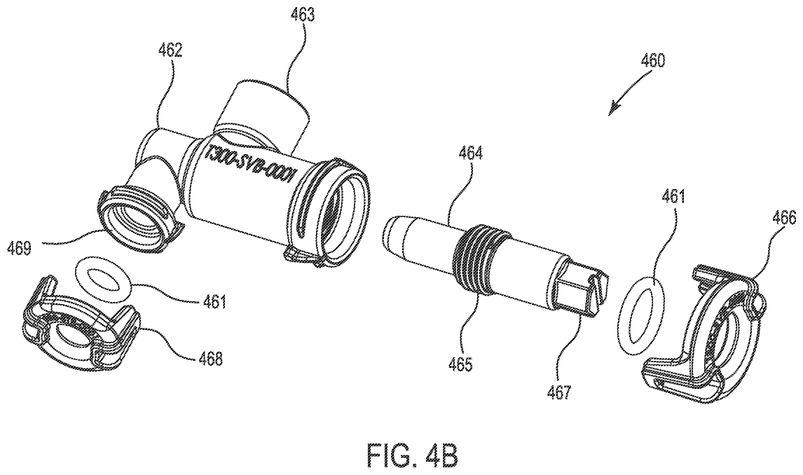

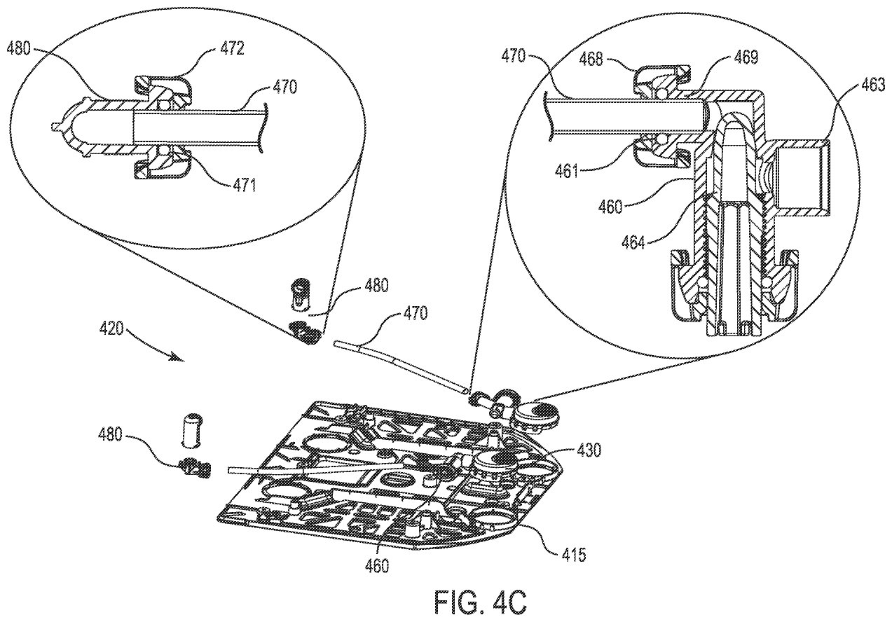

FIGS. 4A, 4B, 4C illustrate a purge gas assembly 420 according to an embodiment. The purge gas assembly 420 is attached to a carrier plate 415 and includes at least two purge modules 430 for distributing purge gas to first and second sides of a substrate container, e.g., 100 of FIG. 1, 200 of FIG. 2, or 300 of FIG. 3.

FIG. 4A is a top view of a purge gas assembly 420, which can have the same or similar features as the purge gas assembly 120 of FIG. 1 or 220 of FIGS. 2A/2B or 320 of FIG. 3. The purge gas assembly 420 includes the at least two gas distributors 430, rear gas distributing devices, e.g., rear diffuser(s) 440, control valve(s) 460, tubing 470, and front gas distributing device(s) 480. The at least two gas distributors 430 can receive the purge modules, as discussed above, e.g., 230 of FIG. 2, 330 of FIG. 3. The purge modules such as 230, 330 can be configured to receive purge gas at an inlet, filter the purge gas, and supply the filtered purge gas to a chamber formed in the purge gas assembly 420. The purge modules such as 230, 330 can be fluidly sealed with a gas distributor to form in combination a chamber, in which a first portion of the purge gas is directed to a first outlet defining a first opening in the gas distributor for distributing purge gas to the rear portion of the substrate container via the rear diffuser(s) 440 and at least a second portion of the purge gas is directed to a second outlet defining a second opening in the gas distributor for distributing purge gas via a second flow path to the front portion of the substrate container to the front gas distributing device(s) 480. The front gas distributing device(s) 480 can include a connection, e.g., an elbow, for fluidly connecting the purge gas assembly 420 to the substrate container or a diffuser for distributing the second portion of the purge gas into the interior space of the substrate container.

The second flow path is formed by having the control valve(s) 460 being connected to the second opening, e.g., 226 of FIG. 2 or 326 of FIG. 3, of the gas distributor, e.g., 222 of FIG. 2 or 322 of FIG. 3, and is configured to control the distribution of the second portion of the purge gas from the purge module 430. The control valve(s) 460 is configured to control the amount of the second portion of the purge gas distributed to the front gas distributing device(s) 480, e.g., divert an amount of purge gas from the rear purge module 430 by controlling pressurization in the chamber. The control of the amount of the purge gas can be set manually, e.g., set by turning of the valve using a hand tool to a set purge gas flow rate, or the amount of purge gas can be set intermittently either manually or automatically, e.g., via automation by a processor-enabled controller setting or providing automatic control to a set point for the purge gas flow, such as when the FOUP is on a load port. The control valve(s) 460 can include needle valves, ball valves, butterfly valves, non-return valves, fixed orifice or similarly structured valves that are used to set the amount of flow of purge gas supplied to the gas distributing device(s). It is appreciated that the amount of purge gas can also be set using an orifice, spring loaded diverter, or piping/pipes that have smaller or larger cross-sectional areas, as needed, to control the amount to purge gas supplied to the front gas distributing device(s) 480.

As illustrated in FIG. 4B, in an embodiment, the control valve 460 can include a valve body 462, a valve needle 464, a valve retainer 466, a tube retainer 468, and sealing rings 461. The valve body 462 includes an inlet 463 that is in the same flow direction as an outlet 469. The inlet 463 can include a snap-fit connection with the second opening of the chamber, in which a sealing ring can be provided between the second opening of the chamber and the inlet 463 of the control valve 460 for fluidly sealing the same. The snap-fit connection can include flexible components that can deform when a force is applied, e.g., using a twisting or pushing force, such that an interlocking occurs with the corresponding components when in the final position, e.g., restoration of the components. While the receiving and supplying of the flow of purge gas is illustrated as being in the same flow direction, e.g., inlet 463 and outlet 469 are parallel, such disclosure is not intended to be limiting, and other flow patterns can be used, e.g., outlet disposed at an angle from the inlet, or the like. Furthermore, the valve body 462 is configured to receive the valve needle 464 which is secured to the valve body using the valve retainer 466 and sealing ring 461. The valve retainer 466 may be snap-fit onto the valve body 462 or attached via other securing mechanisms, such as, cam lock, screw fittings, locking tabs, or the like, in which the sealing ring 461 is disposed between the valve needle 464 and the valve body 462 and valve retainer 466 for fluidly sealing the valve needle 464 to the valve body 462. The valve body 462 and the valve needle 464 can include corresponding threaded portions 465 to allow the precise setting of the control valve 460 to control the precise flow of purge gas to the front gas distributing device(s) 480.

The valve needle 464 can further include a valve head 467 that is configured to provide security, e.g., security device features, to allow the setting of the flow rate of the purge gas to the front gas distributing device(s) and preventing the change of the valve setting once set. In an embodiment, the security device feature can include a cap covering the valve head 467, the valve head 467 having a special design that is only compatible for use with a special tool, e.g., Allen wrench, or star pattern, or specially shaped head, the valve head 467 being sealed, e.g., with a resin or hard material such as metal or plastic, such that the valve head 467 would need to be drilled out for adjusting the valve setting, or a locking mechanism, such as a lock. As such, the control valve 460 can be securely set to supply a predetermined amount of purge gas to the front gas distributing device(s) 480.

FIG. 4C illustrates a top perspective view of the purge gas assembly 420 having the tubing 470 connected to the control valve 460 and the front gas distributing device 480, e.g., an elbow connection for connecting to a front diffuser (not shown) for further forming the second flow path. The tubing 470 can be a flexible polymer tube that is formed from a fluoropolymer, such as, perfluoroalkoxy alkanes (PFA), or polyethylene, such as, high density polyethylene (HDPE), or similar compatible material for substrate processing. In an embodiment, to allow the purge gas assembly 420 to be pre-assembled outside the substrate container on the carrier plate 415, the tubing 470 can be configured to be assembled with a reliable connection system with the control valve 460 or the front gas distributing device 480. In an embodiment, the reliable connection system can include a snap-fit connector 468, 472 and sealing ring 461, 471, such as an O-ring, sealing gasket, or other compressible mechanical gasket material, for example, polymeric or elastomeric material. As such, one end of the tubing 470 can be inserted into the outlet 469 of the control valve 460 and the sealing ring 461 placed along an outer surface of the tubing 470, such that when the snap-fit connector 468 is snapped together with the outlet 469 of the control valve 460, the sealing ring 461 is compressed to fluidly seal the tubing 470 with the control valve 460. Similarly, the other end of the tubing 470 can be inserted into the front gas distributing device 480 and the sealing ring 471 placed along an outer surface of the tubing 470, such that when the snap-fit connector 472 is snapped to the front gas distributing device 480, the sealing ring 471 is compressed to fluidly seal the tubing 470 with the front gas distributing device 480. The snap-fit connector 468, 472 can include flexible components that can deform when a force is applied, e.g., using a twisting or pushing force, such that an interlocking occurs with the corresponding component on the outlet 469 or front gas distributing device 480 when in the final position, e.g., restoration of the components. As such, a reliable connection system can be provided for pre-assembling the purge gas assembly 420 on a carrier plate 415, such that the purge gas assembly 420 can be pre-assembled and when the carrier plate 415 and purge gas assembly 420 are attached to a substrate container, the purge module, and optionally including the diffuser, can be inserted into the substrate container from outside the substrate container with no or minimal intrusion into the interior space of the substrate container for assembling of the same.

The front gas distributing device 480 can be an elbow that connects to the input purge port, e.g., 110 of FIG. 1, or a diffuser or manifold inserted through the bottom wall of the substrate container. When the front gas distributing device 480 is an elbow, the front gas distributing device 480 can be attached or locked into the side wall of the substrate container, e.g., via input purge port, and the diffuser or manifold can then be connected to the front gas distributing device 480 via minimal operations inside the container body. In some embodiments, the front gas distributing device 480 can be configured such that the diffuser or manifold can be removed or replaced by simply rotating the diffuser or manifold to lock or unlock from the front gas distributing device 480.

As such, a simple and effective purge gas assembly can be provided to transport purge gas from an inlet and a rear purge module to a front gas distributing device via a flexible polymer tube through the shell of the substrate container without having to modify the substrate container or drill holes into the carrier plate, in which the components can be simply twist-locked or snap-fit connected together to provide reliable connection. Such purge gas flow distribution can be routed within existing FOUP geometries with minimal modifications, e.g., since the pre-assembly of the purge gas assembly can be done externally of the substrate container.

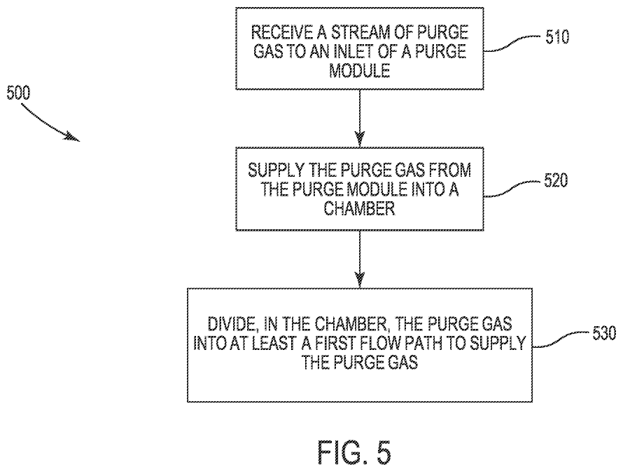

FIG. 5 shows a flowchart of a method of controlling a flow of purge gas through the purge gas assembly according to an embodiment. Method 500 includes receiving a stream of purge gas at an inlet of a purge module at 510, supplying the purge gas from an outlet of the purge module into a chamber formed by a combination of the purge module and a gas distributor of a purge gas assembly, the gas distributor having at least one outlet purge module at 520, and dividing, in the chamber, the purge gas into at least a first flow path to supply the purge gas to the at least one outlet of the gas distributor at 530.

A stream of purge gas is received at an inlet of the purge module at 510. The purge module can include an inlet, a check valve for regulating a flow direction of the purge gas, a module body, and an outlet. At the inlet, a stream of purge gas is received from a purge gas supply system. The purge gas supply system delivers purge gas which may generally be an inert gas. The purge gas can include, for example, but is not limited to, one or more of nitrogen, clean dry air (CDA), and extra clean dry air (xCDA). The check valve is received in the module body and configured to allow the flow of purge gas in only one direction from the inlet to the outlet through the module body. The module body defines one or more passages or passageways from the inlet for passing the purge gas through the purge module and the check valve. The purge module can further include a filter disposed before or after the outlet, a filter retainer for retaining the filter on the purge module, a diffuser retainer configured to support the diffuser, and the diffuser attached to the purge module or the purge gas assembly. The filter retainer and the diffuser retainer can be configured such that the purge gas exiting the outlet is divided or distributed such that a first portion of the flow of purge gas through the filter enters the first opening by at least being partially connected to the diffuser and a second portion of the flow of purge gas through the filter passes through one or more apertures defined by one or both of the filter retainer and the diffuser retainer and enters at least the chamber. The filter can remove any suitable contaminants such as volatile organic compounds, particulate matter, and the like, based on the structure and composition of the media used in the filter. As such, the supplying of the stream of purge gas can include one or more of the following: directing the purge gas through a check valve of the purge module into a passageway defined in a module body of the purge module; directing the purge gas from the passageway to a filter through one or more passages in the module body; directing a first portion of the purge gas from the filter and a filter retainer into the first flow path to the first gas distributing device; and directing a second portion of the purge gas from the filter through one or more apertures defined by one or both of a filter retainer and a diffuser retainer out of the purge module into the second flow path to the second gas distributing device.

The purge gas is supplied from the purge module into a chamber formed by a combination of a purge module and a gas distributor of a purge gas assembly at 520. The purge gas assembly includes the gas distributor which has at least one outlet and the purge module, in which the gas distributor and the purge module in combination form a chamber for receiving the purge flow. In an embodiment, the gas distributor has at least one first outlet that defines the first opening for directing a first flow path of a first portion of a purge gas for distributing to the rear portion of the substrate container and at least one second outlet that defines the second opening for directing a second flow path of a second portion of the purge gas for distributing the purge gas to a front portion of the substrate container. In an embodiment, the purge module is inserted into the chamber and the diffuser is attached to the purge module and inserted into the rear portion of the substrate container via an inlet purge port to form a sealing arrangement. As such, the purge gas exiting the outlet of the purge module is supplied into the chamber that surrounds at least the outlet of the purge module. While the gas distributor and chamber has been discussed with respect to two outlets, such disclosure is not intended to be limiting. For example, the gas distributor or chamber can have a single outlet or single opening or three or more outlets or openings for supplying purge gas to a gas distributing device in the interior of the substrate container.

The purge gas is divided in the chamber into at least a first flow path to supply the purge gas to the at least one outlet of the gas distributor at 530. After the purge gas exiting the outlet of the purge module is supplied into the chamber, the purge gas is divided within the chamber in which a first portion of the purge gas can be directed to the first opening and a second portion of the purge gas can be directed to the second opening. The first portion of the purge gas can be directed to the first opening of the chamber via the purge module, e.g., a diffuser retainer or diffuser inlet, or by the chamber itself, e.g., passageway in the chamber that receives the purge gas and directs the purge gas to the first opening. The second portion of the purge gas can be directed to the second opening of the chamber by supplying the purge gas though one or more apertures defined at the exit of the purge module into the chamber, e.g., not passing through the diffuser inlet. The second portion of the purge gas can be sent via the second flow path to front gas distributing devices for distributing the second portion of the purge gas in the front portion of the substrate container. The second flow path of the purge gas for the second portion can further include regulating a flow of the purge gas in the second flow path to the second gas distributing device, for example, by controlling a valve to regulate the flow of the purge gas through the second flow path to the second gas distributing device. As such, a pressurization of the chamber can be controlled by the valve to regulate or distribute a flow of purge gas in the second flow path, some of the purge gas flows through the valve and some through the first opening, e.g., the rear diffuser 240. As such, the purge gas is divided or distributed within the chamber for supplying purge gas, for example, to a front diffuser via second opening and the rear diffuser via first opening for distributing the purge gas into the interior space of the substrate container.

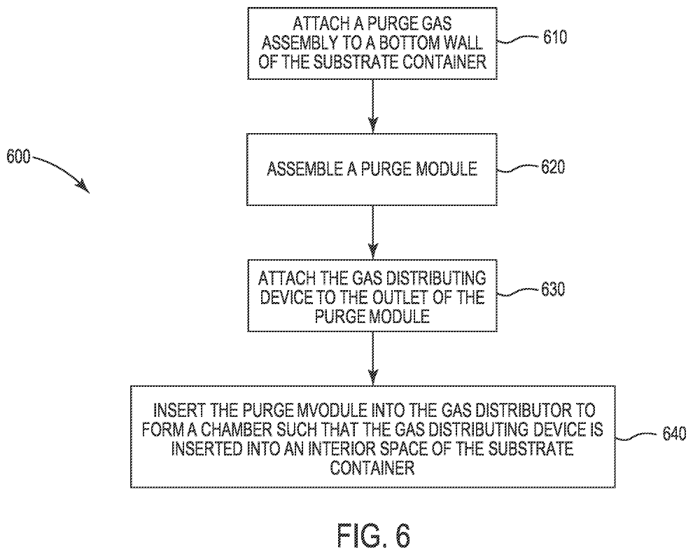

FIG. 6 shows a flowchart of a method of assembling a substrate container having a gas distributing device, according to an embodiment. Method 600 includes attaching a purge gas assembly to a bottom wall of the substrate container at 610; assembling a purge gas assembly at 620; attaching the gas distributing device to the outlet of the purge module at 630; and inserting the purge module into the gas distributor to form a chamber such that the gas distributing device is inserted into an interior space of the substrate container through the at least one outlet of the gas distributor at 640.

A purge gas assembly is attached to a bottom wall of the substrate container 610. The attaching of the purge gas assembly to the substrate container can include a pre-assembly step. In the pre-assembly step, a purge gas assembly that includes tubing, valve(s), and a gas distributor can be attached or molded together with a top surface of a carrier plate. In some embodiments, the pre-assembly can include one or more of: attaching tubing to connect the second opening of the chamber to a second gas distributing device; snap-fitting a snap-fit connection on the tubing and the second opening of the chamber or snap-fitting a snap-fit connection on the tubing and the second gas distributing device; attaching a control valve to the second opening of the chamber for regulating the flow of purge gas; and snap-fitting a snap-fit connection on an inlet of the control valve to the second opening of the chamber. While the attachment of the purge gas assembly to a carrier plate is discussed herein, it is understood that such disclosure is not intended to be limiting. For example, in an embodiment, the purge gas assembly can be stand-alone unit for installation to the substrate container. When assembling the substrate container, the carrier plate including the purge gas assembly can be attached to the bottom wall of the substrate container to define the bottom plate of the substrate container to form a complete substrate container system. The attachment of the carrier plate can be securely fixed, e.g., using tabs, screws, or other fastening devices, and not intended to be able to be disassembled to be integrally formed or removably attachable, as necessary.

A purge module is assembled at 620. The assembling of the purge module includes assembling the purge module to include an inlet for receiving a flow of purge gas, a check valve for regulating a flow direction of the purge gas, and an outlet for supplying the purge gas.

Optionally, a gas distributing device can be attached at 630. The assembling can further include attaching the gas distributing device to the outlet of the purge module. The gas distributing device can be a diffuser, manifold, membrane, portions having slits or nozzles or is made of porous material, elbows, or flow diverters, or similar structures that is able to direct the purge gas into the interior of the substrate container, and combinations of the same. The attachment can include using a diffuser retainer or the gas distributing device can be attached directly to the purge module. In some embodiments, the different retainer is configured to direct purge gas to the gas distributing device, e.g., via a flared inlet. It is appreciated that in some embodiments the gas distributing device can be optionally attached to the purge module. In other embodiments, a plug or stopper can be provided to control the distribution of flow into the chamber.

The purge module can be inserted into the gas distributor to form a chamber at 640. In further assembling the substrate container, the purge module including the gas distributing device is inserted into the gas distributor to form a chamber that surrounds at least the outlet of the purge module such that the gas distributing device is inserted into an interior space of the substrate container through the at least one outlet of the gas distributor for dividing the purge gas into at least a first flow path. In an embodiment, the gas distributor includes a first outlet that defines a first opening for directing the first flow path to the gas distributing device for distributing a first portion of the purge gas. In some embodiments, the gas distributor can include a second outlet that defines a second opening for directing the second flow path to at least one second gas distributing device for distributing a second portion of the purge gas. As such, since the purge gas assembly can be pre-assembled, the pre-assembled purge gas assembly can be attached externally of the substrate container and the purge module subsequently attached such that the gas distributing device, e.g., diffuser or manifold, can be inserted into the substrate container from outside the substrate container with no or minimal intrusion into the interior space of the substrate container. Thus, the assembly of the substrate container can be performed mostly or all externally of the substrate container.

In some embodiments, the attaching of the purge gas assembly can further include attaching a second purge gas assembly to the carrier plate prior to attaching the carrier plate to the bottom wall of the substrate, in which the second purge gas assembly includes a second gas distributor having at least one outlet. Furthermore, the inserting the purge module can further include inserting a second purge module having a second gas distributing device into the second gas distributor to form a second chamber that surrounds at least the outlet of the purge module such that the second gas distributing device is inserted into the interior space of the substrate container through the at least one outlet of the second gas distributor.

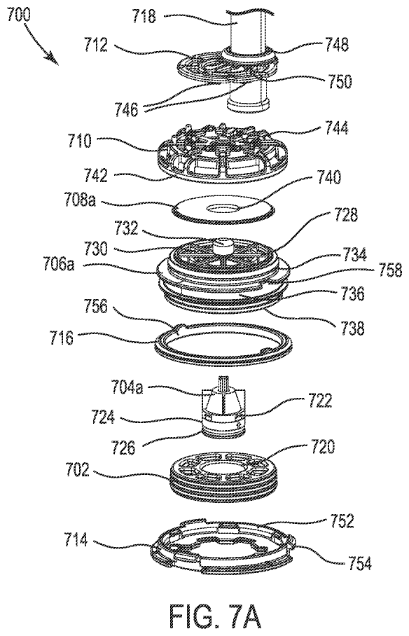

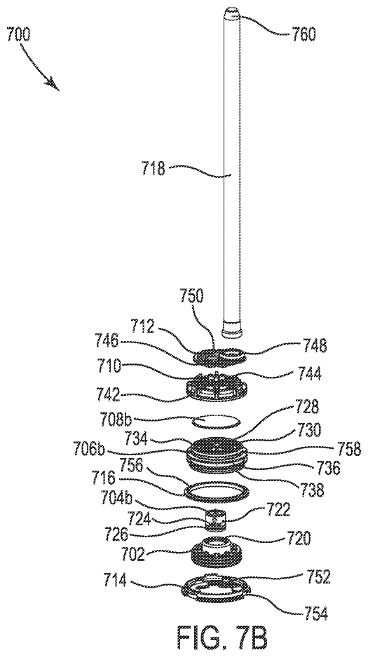

FIG. 7A shows an exploded view of a purge module according to an embodiment, which can be the same or similar as the purge modules 130, 230, 330, or 430 as discussed above. Purge module 700 includes grommet 702, check valve 704, module body 706, filter 708, filter retainer 710, and diffuser retainer 712. Optionally, a module retainer 714 can be included in purge module 700. Optionally, a lip seal 716 can be included in purge module 700. Optionally, a diffuser 718 can be included in purge module 700. The lip seal 716 can be a circular sealing member configured to be received in lip seal groove 736.

Purge module 700 is a module configured to be received in a purge port of a substrate container. In an embodiment, purge module 700 is configured to be received in a rear purge port of a substrate container. In an embodiment, purge module 700 is configured to be received in a chamber configured to accept filtered purge gas from the purge module 700 and direct a portion of the purge gas to another purge distribution structure, such as second or front gas distributing device 180 described above and shown in FIG. 1.

Purge module 700 includes grommet 702. Grommet 702 can be made of a resilient material. In an embodiment, the resilient material can be a fluoroelastomer, for example Viton™, FKM, a thermoplastic elastomer, a thermoplastic olefin, a thermoplastic polyurethane, or the like. The grommet can include an aperture configured to receive a flow of purge gas from a purge gas source, such as a port provided on a tool where the substrate container including purge module 700 is to be used. The grommet 702 can further include a portion configured to receive check valve 704, such that check valve 704a can receive the purge gas introduced at the aperture of grommet 702. The grommet 702 can include a groove 720 configured to engage with a projection 722 formed on check valve 704a such that check valve 704a is secured to grommet 702.

Check valve 704a is a valve configured to permit flow through check valve 704a into the module body 706, and obstruct flow from module body 706a back through the check valve 704. Check valve 704a can be any suitable check valve, such as an umbrella valve assembly, a spring-loaded valve assembly, or the like. At least a portion of check valve 704a can be inserted into a recess formed in the grommet 702. Check valve 704a can include projection 722 configured to engage with grommet 702 at groove 720. In an embodiment, the projection 722 can be an annular projection. In an embodiment, check valve 704a can include seal groove 724. Seal groove 724 can accommodate seal 726. Seal 726 can be any suitable member for forming a seal between the check valve 704a and grommet 702, such as an O-ring, a gasket, or the like.

Module body 706a is configured to receive the grommet 702 and check valve 704. The module body 706a can be made of a rigid material such as polycarbonate materials. In an embodiment, carbon fiber fill can be included in the material used to form module body 706. Module body 706a can include a filter-facing surface 728 including the ends of one or more passages 730. A projection 732 can be provided from the filter-facing surface 728 of module body 706. Module body 706a can further include a first snap-fit feature 734 configured to allow filter retainer 710 to be snap-fit to the module body 706. In an embodiment, module body 706a can include a lip seal groove 736 configured to accommodate the lip seal 716. The lip seal 716 can be a circular sealing member configured to be received in lip seal groove 736. In an embodiment, module body 706a can include a second snap-fit feature 738 configured to form a snap-fit with module retainer 714. Module body 706a and grommet 702 can be configured such that module body 706a and grommet 702 can be retained to one another by a press-fit.

Filter 708 can be any suitable filter for filtering the purge gas. The filter 708 can include any suitable filter media for removing contaminants such as particulate matter, volatile organic compounds, or the like from the purge gas as it passes through filter 708. In an embodiment, filter 708 can include an opening defined by inner perimeter 740. The opening defined by inner perimeter 740 can be configured to accommodate the projection 732 of module body 706, such that filter 708 surrounds a portion of the module body 706a when purge module 700 is assembled. In an embodiment, the projection 732 can be omitted from the module body 706, and a filter 708 that does not possess an opening can be used.

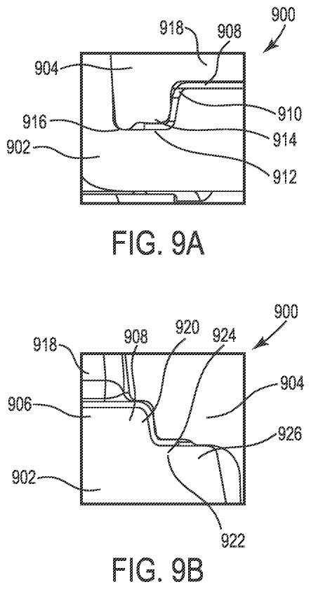

Filter retainer 710 is configured to be attached to module body 706a to retain filter 708 between the module body 706a and filter retainer 710. Filter retainer 710 can include snap-fit ring 742 configured to form a snap-fit with the first snap-fit feature 734 of module body 706. Filter retainer 710 can be made of a rigid material such as polycarbonate materials. Filter retainer 710 can be configured to clamp the outer perimeter of the filter 708 against module body 706, for example as shown in FIG. 9B and discussed below. In embodiments where the filter 708 includes the opening defined by inner perimeter 740, the filter retainer 710 and module body 706a can be configured to clamp the filter 708 at inner perimeter 740. The filter retainer 710 includes a grill 744 defining a plurality of openings. In an embodiment, the openings can allow at least some of the flow of purge gas through purge module 700 to leave the purge module 700.

Diffuser retainer 712 is configured to support a diffuser, such as diffuser 718. Diffuser retainer 712 is further configured to attach to the filter retainer 710, for example by way of a snap-fit. A snap-fit between the diffuser retainer 712 and the filter retainer 710 can be formed by way of diffuser retainer snap-fit features 746, which can be configured to engage with features of the filter retainer 710 such as portions of grill 744. Diffuser retainer 712 can be made of a rigid material such as polycarbonate materials. Diffuser retainer 712 includes a diffuser inlet 748 which is configured to receive the diffuser 718 and can direct flow of purge gas into the diffuser 718. Diffuser retainer 712 can, alone or in combination with the filter retainer 710, define one or more openings by which a portion of the purge gas can leave the purge module 700 without passing into the diffuser inlet 748. For example, as shown in FIGS. 7A and 7B, the diffuser retainer 712 can include a grill 750 to allow purge gas to leave the purge module 700 without passing into diffuser inlet 748. Purge gas that does not enter diffuser inlet 748 can pass into a chamber, for example the chamber formed by the combination of the gas distributor 222 and the purge module 230 described above and shown in FIG. 2. In an embodiment, the filter retainer 710 can provide additional support to the diffuser 718 such that the diffuser 718 is retained at diffuser inlet 748 of the diffuser retainer 712. In an embodiment, the diffuser inlet 748 is positioned such that the diffuser 718 is within a perimeter of the module body 706. In an embodiment, the diffuser 718 is not offset from the module body 706. In an embodiment, when purge module 700 is viewed in plan view, the diffuser 718 is disposed with the perimeter of the module body 706. The diffuser 718 and purge module 700 can be installed into the substrate container from an exterior of the substrate container as a complete assembly, for example by inserting the diffuser through an aperture in the substrate container and then continuing to insert the purge module into the aperture. This can avoid a need to install the diffuser 718 through operations on an inside of the substrate container, reducing risk of introducing contaminants such as particulate matter from such operations. In an embodiment, diffuser retainer 712 can instead include a cap (not shown) in place of the diffuser 718. The cap can be a separate element retained in diffuser inlet 748, or can be integrally formed over diffuser inlet 748.

Module retainer 714 can optionally be included to secure the purge module 700 to a substrate container. Module retainer 714 can be made of a rigid material such as polycarbonate materials. Module retainer 714 includes one or more snap-fit features 752 configured to engage with the second snap-fit feature 738 provided on module body 706. In an embodiment, the snap-fit formed between the one or more snap-fit features 752 and second snap-fit feature 738 can be such that module retainer 714 can be rotated through a full 360° when the module retainer 714 is snap-fit to the module body 706. The module retainer 714 is configured to mechanically engage with the substrate container at an aperture of the substrate container where purge module 700 is received. For example, module retainer 714 can include a plurality of container engagement features 754 configured to be inserted into the substrate container when in a first position, and to engage with the substrate container to retain purge module 1700 when module retainer 714 is rotated into a second position. The container engagement features 754 can have any suitable shape that can provide insertability in a first position and engagement when rotated into a second position.

Lip seal 716 can optionally be included to provide a seal between module body 706a and the substrate container which purge module 700 is installed into. Lip seal 716 can be a resilient material, such as a fluoroelastomer, for example Viton™ or FKM., a thermoset elastomer, a thermoplastic elastomer, a thermoplastic olefin, a thermoplastic polyurethane, or the like. The lip seal 716 can be a circular sealing member configured to be received in lip seal groove 736. Lip seal 716 can include anti-rotation features 756 configured to engage notches 758 formed in lip seal groove 736 of module body 706a.

Diffuser 718 can be included in purge module 700. Diffuser 718 can be a tube formed of a porous material, configured to release the purge gas received by diffuser 718 within a substrate container that purge module 700 is installed into. Diffuser 718 includes an open end configured to receive purge gas that can be provided at diffuser inlet 748. Diffuser 718 can further include a closed end, which can be, for example, a flat closed end, a hemispherical closed end, a flat closed end with a bevel or radiusing at the transition from the body of diffuser 718 to said closed end, or the like. Diffuser 718 can be retained in position by diffuser retainer 712 or a combination of filter retainer 710 and diffuser retainer 712.

FIG. 7B shows an exploded view of a purge module according to an embodiment. In the embodiment shown in FIG. 7B, the check valve 704b is sized such that module body 706b can accommodate check valve 704b without including the projection 732 shown in FIG. 7A. Other features of check valve 704b can be as described for check valve 704a, other than differences in the sizing and/or shape relative to the corresponding module body 706a,b. The module body 706b can otherwise as described for module body 706a, aside from an absence of the projection 732 provided on module body 706a. The filter 708b can be a continuous disc, with no opening defined by an inner perimeter 740 as shown in FIG. 7A. Accordingly, filter 708b can be retained by clamping at the outer perimeter thereof, for example according to the clamping shown in FIG. 9B and described below. In an embodiment, this clamping at the outer perimeter of filter 708b can be the only attachment fixing the filter 708b in place in the purge module 700. Other features of filter 708b can be as described for filter 708a. As can be seen in FIG. 7B, diffuser 718 includes a bevel or chamfer 760 at an end thereof.

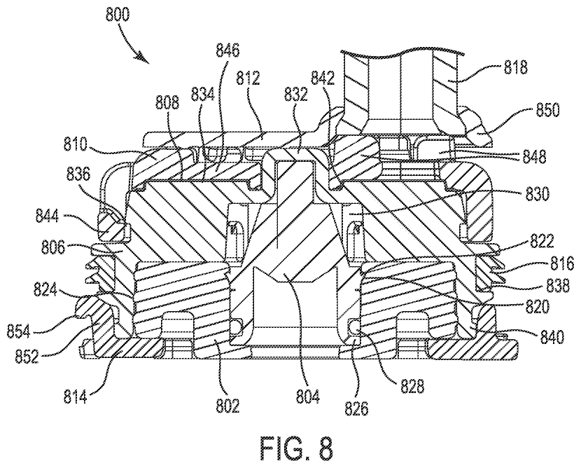

FIG. 8 shows a sectional view of a purge module according to an embodiment. Purge module 800 includes grommet 802, check valve 804, module body 806, filter 808, filter retainer 810, and diffuser retainer 812. Optionally, a module retainer 814 can be included in purge module 800. Optionally, a lip seal 816 can be included in purge module 800. Optionally, a diffuser 818 can be included in purge module 800.

Purge module 800 is a module configured to be received in a purge port of a substrate container. In an embodiment, purge module 800 is configured to be received in a rear purge port of a substrate container. In an embodiment, purge module 800 is configured to be received in a chamber configured to accept filtered purge gas from the purge module 800 and direct a portion of the purge gas to another purge distribution structure, such as second or front gas distributing device 180 described above and shown in FIG. 1.

Grommet 802 can be made of a resilient material. In an embodiment, the resilient material can be a fluoroelastomer, for example Viton™, FKM, a thermoplastic elastomer, a thermoplastic olefin, a thermoplastic polyurethane, or the like. The grommet can include an aperture configured to receive a flow of purge gas from a purge gas source, such as a port provided on a tool where the substrate container including purge module 800 is to be used. The grommet 802 can further include a portion configured to receive check valve 804, such that check valve 804 can receive the purge gas introduced at the aperture of grommet 802. The grommet 802 can include a groove 820 configured to engage with a projection 822 formed on check valve 804 such that check valve 804 is secured to grommet 802. Grommet 802 can further include ribs 824 configured to engage module body 806 to further secure the fit of grommet 802 within module body 806 when the purge module 800 is assembled.

Check valve 804 is a valve configured to permit flow through check valve 804 into the module body 806, and obstruct flow from module body 806 back through the check valve 804. Check valve 804 can be any suitable check valve, such as an umbrella valve assembly, a spring-loaded valve assembly, or the like. At least a portion of check valve 804 can be inserted into an opening or recess formed in the grommet 802. Check valve 804 can include projection 822 configured to engage with grommet 802 at groove 820. In an embodiment, the projection 822 can be an annular projection. In an embodiment, check valve 804 can include seal groove 826. Seal groove 826 can accommodate seal 828. Seal 828 can be any suitable member for forming a seal between the check valve 804 and grommet 802, such as an O-ring, a gasket, or the like. A portion of check valve 804 extends into a portion of cavity 830 within module body 806.

Module body 806 is configured to receive the grommet 802 and check valve 804. The module body 806 can be made of a rigid material such as polycarbonate materials. In an embodiment, carbon fiber fill can be included in the material used to form module body 806. Module body 806 can define a cavity 830. The cavity 830 can include a first portion configured to receive grommet 802. The first portion of cavity 830 can be configured such that the module body 806 and grommet 802 are retained to one another by a press-fit. The cavity can include a second portion configured to accommodate a portion of check valve 804 that protrudes from grommet 802 when the check valve 804 is installed into the grommet 802. The module body 806 can optionally include a projection 832 protruding beyond filter-facing surface 834 of the module body 806. The cavity 830 can include a portion defined by the projection 832, for example a portion of cavity 830 capable of receiving a part of the check valve 804. Module body 806 includes one or more passages (not shown as the section of FIG. 8 is taken across solid ribs defining said passages) from the cavity 830 to filter-facing surface 834, such as the passages 730 described above and shown in FIGS. 7A and 7B. Module body 806 can further include a first snap-fit feature 836 configured to allow filter retainer 810 to be snap-fit to the module body 806. In an embodiment, module body 806 can include a lip seal groove 838 configured to accommodate the lip seal 816. In an embodiment, module body 806 can include a second snap-fit feature 840 configured to form a snap-fit with module retainer 814.

Filter 808 can be any suitable filter for filtering the purge gas. The filter 808 can include any suitable filter media for removing contaminants such as particulate matter, volatile organic compounds, or the like from the purge gas as it passes through filter 808. In an embodiment, filter 808 can include an opening defined by inner perimeter 842. The opening defined by inner perimeter 842 can be configured to accommodate the projection 832 of module body 806, such that filter 808 surrounds a portion of the module body 806 when purge module 800 is assembled. In an embodiment, the projection 832 can be omitted from the module body 806, and a filter 808 that does not possess an opening can be used.

Filter retainer 810 is configured to be attached to module body 806 to retain filter 808 between the module body 806 and filter retainer 810. Filter retainer 810 can include snap-fit ring 844 configured to form a snap-fit with the first snap-fit feature 836 of module body 806. Filter retainer 810 can be made of a rigid material such as polycarbonate materials. Filter retainer 810 can be configured to clamp the outer perimeter of the filter 808 against module body 806, for example as shown in FIG. 9B and discussed below. In embodiments where the filter 808 includes the opening defined by inner perimeter 842, the filter retainer 810 and module body 806 can be configured to clamp the filter 808 at inner perimeter 842. The filter retainer 810 includes a grill 846 defining a plurality of openings. In an embodiment, the openings can allow at least some of the flow of purge gas through purge module 800 to leave the purge module 800. Diffuser retention projections 848 can be included on filter retainer 810. The diffuser retention projections 848 can be configured such that when a diffuser 818 is installed in diffuser retainer 812 and the diffuser retainer 812 is attached to filter retainer 810, the diffuser is secured between the diffuser retention projections 848 and one or more suitable features of the diffuser retainer 812, such as diffuser inlet 850.

Diffuser retainer 812 is configured to support a diffuser, such as diffuser 818. Diffuser retainer 812 is further configured to attach to the filter retainer 810, for example by way of a snap-fit. Diffuser retainer 812 can be made of a rigid material such as polycarbonate materials. Diffuser retainer 812 includes a diffuser inlet 850 which is configured to receive the diffuser 818 and can direct flow of purge gas into the diffuser 818. Diffuser retainer 812 can, alone or in combination with the filter retainer 810, define one or more openings by which a portion of the purge gas can leave the purge module 800 without passing into the diffuser inlet 850. Purge gas that does not enter diffuser inlet 850 can pass into a chamber, for example a chamber formed by the combination of the gas distributor 222 and the purge module 230 described above and shown in FIG. 2. In an embodiment, the filter retainer 810 includes diffuser retention projections, which press the diffuser 818 into diffuser inlet 850 such that diffuser 818 is held within diffuser inlet 850 by the combination of filter retainer 810 and diffuser retainer 812. In an embodiment, the diffuser inlet 850 is positioned such that the diffuser 818 is within a perimeter of the module body 806. In an embodiment, the diffuser 818 is not offset from the module body 806. In an embodiment, when purge module 800 is viewed in plan view, the diffuser 818 is disposed with the perimeter of the module body 806. The diffuser 818 and purge module 800 can be installed into the substrate container from an exterior of the substrate container as a complete assembly, for example by inserting the diffuser through an aperture in the substrate container and then continuing to insert the purge module into the aperture. This can avoid a need to install the diffuser 818 through operations on an inside of the substrate container, reducing risk of introducing contaminants such as particulate matter from such operations. In an embodiment, diffuser retainer 812 can instead include a cap (not shown) in place of the diffuser 818. The cap can be a separate element retained in diffuser inlet 850, or can be integrally formed over diffuser inlet 850.

Module retainer 814 can optionally be included to secure the purge module 800 to a substrate container. Module retainer 814 can be made of a rigid material such as polycarbonate materials. Module retainer 814 includes one or more snap-fit features (not shown), such as the snap-fit features 752 described above and shown in FIGS. 7A and 7B, configured to engage with the second snap-fit feature 840 provided on module body 806. In an embodiment, the snap-fit formed with the second snap-fit feature 840 can be such that module retainer 814 can be rotated through a full 360° when the module retainer 814 is snap-fit to the module body 806. The module retainer 814 is configured to mechanically engage with the substrate container at an aperture of the substrate container where purge module 800 is received. For example, module retainer 814 can include a plurality of container engagement features 852 configured to be inserted into the substrate container when in a first position, and to engage with the substrate container to retain purge module 800 when module retainer 814 is rotated into a second position. The container engagement features 852 can have any suitable shape that can provide insertability in a first position and engagement when rotated into a second position, such as the hook-shaped cross section visible in FIG. 8. In the embodiment shown in FIG. 8, the container engagement feature 852 includes a container contact surface 854 configured to contact a flange or other suitable feature provided in the substrate container where purge module 800 is inserted.

Lip seal 816 can optionally be included to provide a seal between module body 806 and the substrate container which purge module 800 is installed into. Lip seal 816 can be a resilient material, such as a fluoroelastomer, for example Viton™ or FKM. The lip seal 816 can be a circular sealing member configured to be received in lip seal groove 838.

Diffuser 818 can be included in purge module 800. Diffuser 818 can be a tube formed of a porous material, configured to release the purge gas received by diffuser 818 within a substrate container that purge module 800 is installed into. Diffuser 818 includes an open end configured to receive purge gas that can be provided at diffuser inlet 850. Diffuser 818 can be retained in position by diffuser retainer 812 or a combination of filter retainer 810 and diffuser retainer 812. For example, diffuser 818 can be held between the diffuser inlet 850 and one or more diffuser retention projections 848 provided on the filter retainer 810. Diffuser 818 can further include a closed end, which can be, for example, a flat closed end, a hemispherical closed end, a flat closed end with a bevel or radiusing at the transition from the body of diffuser 818 to said closed end, or the like.

FIG. 9A shows a sectional view of a purge module at an inner circumference of a filter according to an embodiment. Purge module 900 includes module body 902 and filter retainer 904. Filter 906, shown in FIG. 9B, is retained between module body 902 and filter retainer 904. Module body 902 includes filter-facing surface 908, inner shoulder 910, and inner module body clamping surface 912. Filter retainer 904 includes inner filter retainer clamping surface 914, inner contact surface 916, and filter grill 918.

Module body 902 is a body of purge module 900. Module body 902 is configured such that filter retainer 904 can be attached to the module body 902, for example by providing one or more snap-fit features. Module body 902 can be, for example, module body 706a,b or module body 806 as described above and shown in FIGS. 7A and 7B and FIG. 8, respectively.

Filter retainer 904 is configured to attach to module body 902 such that filter 906, shown in FIG. 9B, is retained between the module body 902 and filter retainer 904. The filter retainer can be con figured to be attached to module body 902 by, for example, a snap-fit, for example by providing one or more snap-fit features that are configured to interface with a corresponding one or more snap-fit features provided on the module body 902. The filter retainer 904 can be, for example, filter retainer 710 or filter retainer 810 as described above and shown in FIGS. 7A and 7B and FIG. 8, respectively.

Filter 906, shown in FIG. 9B, is a filter configured to be placed between module body 902 and filter retainer 904. The filter 906, shown in FIG. 9B, can include any suitable filter media, such as filter media to remove one or more contaminants selected from particulate matter, volatile organic compounds, or the like. The filter 906, shown in FIG. 9B, can be shaped to cover passages through the module body 902, such that fluid passing through the module body 902 then is directed to the filter 906, shown in FIG. 9B. Filter 906, shown in FIG. 9B, can include an opening defined by an inner perimeter. The inner perimeter can surround a projection extending from module body 902.

Filter-facing surface 908 is provided on the module body 902. The passages through the module body 902 can terminate at the filter-facing surface 908. Filter-facing surface 908 extends to inner shoulder 910. Inner shoulder 910 is a transition from the filter-facing surface 908 to a vertical surface, extending towards inner module body clamping surface 912. The filter 906 can be bent over the inner shoulder 910, following the space defined between module body 902 and filter retainer 904. The inner module body clamping surface 912 is a surface separate and offset from filter-facing surface 908.

The filter retainer 904 includes inner filter retainer clamping surface 914. The inner filter retainer clamping surface 914 is configured to oppose the inner module body clamping surface 912 when the filter retainer 904 is attached to module body 902. The filter 906 can be compressed between inner module body clamping surface 912 and inner filter retainer clamping surface 914, such that filter 906 allows reduced or no flow to pass through a side edge of the filter 906 at the inner perimeter of filter 906.

Inner contact surface 916 is a surface of the filter retainer 904 configured to directly contact the module body 902. The inner contact surface 916 can be inside an inner perimeter of the filter 908 relative to a central axis of purge module 900, such that direct contact can be made between the filter retainer 904 and module body 902.

Filter grill 918 is the grill of filter retainer 904 configured to retain the filter 906, shown in FIG. 9B, in place while allowing flow through filter 906, shown in FIG. 9B, to pass through the filter retainer 904. Filter grill 918 can include any suitable structure for retaining the filter 906, shown in FIG. 9B, when flow passes through said filter 906.

FIG. 9B shows a sectional view of a purge module of FIG. 9A at an outer circumference of a filter according to an embodiment. At the outer circumference of filter 906 shown in FIG. 9B, module body 902 includes the filter-facing surface 908, outer shoulder 920, and outer module body clamping surface 922. Filter retainer 904 includes filter grill 918, outer filter retainer clamping surface 924, and outer contact surface 926. Filter-facing surface 908 extends to the outer shoulder 920. At outer shoulder 920, the module body transitions from the filter-facing surface to a portion extending to outer module body clamping surface 922. Outer module body clamping surface 922 can surround the filter-facing surface 908 of the module body 902. The outer filter retainer clamping surface 924 is provided on filter retainer 902. The outer filter retainer clamping surface 924 is configured to oppose the outer module body clamping surface 922, such that filter 906 can be compressed between outer module body clamping surface 922 and outer filter retainer clamping surface 924, such that filter 906 allows reduced or no flow to pass through a side edge of the filter 906 at the outer perimeter of filter 906. Filter retainer 904 further includes outer contact surface 926 is a surface of the filter retainer 904 configured to directly contact the module body 902. The outer contact surface 926 can be outside an outer perimeter of the filter 908, such that direct contact can be made between the filter retainer 904 and module body 902. As shown in FIGS. 9A and 9B, module body 902 and filter retainer 904 can clamp filter 906 at the inner perimeter thereof at inner module body clamping surface 912 and inner filter retainer clamping surface 914, and at the outer perimeter thereof at outer module body clamping surface 922 and outer filter retainer clamping surface 924. The filter 906 can thus be sealed at both the inner perimeter and the outer perimeter when the filter 906 includes an opening.

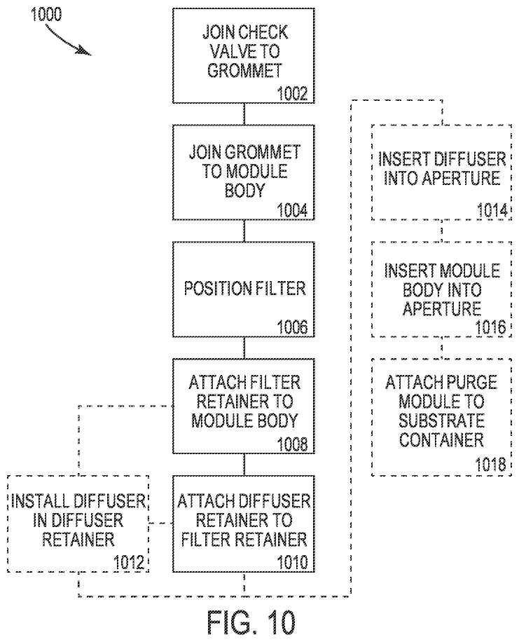

FIG. 10 shows a flowchart of a method for assembling a purge module according to an embodiment. Method 1000 includes joining a check valve to a grommet at 1002, joining the grommet to a purge module body at 1004, positioning a filter at 1006, attaching a filter retainer to the purge module body at 1008, and attaching a diffuser retainer to the filter retainer at 1010. Optionally assembling the purge module can further include installing a diffuser at 1012. Optionally, method 1000 can further include inserting the diffuser through an aperture on a substrate container 1014, inserting at least a portion of the purge module into the aperture at 1016, and/or attaching the purge module to the substrate container using a module retainer at 1018.

The check valve is joined to the grommet at 1002. The check valve can be joined to the grommet by inserting the check valve into an opening of the grommet and forming a press-fit between the grommet and the check valve. In an embodiment, the grommet and/or the check valve include engagement features to secure the attachment of the grommet to the check valve, such as, for example, annular projections and/or annular grooves provided on one of the grommet and the check valve configured to interface with surfaces on the other of the grommet and the check valve. The connection of the check valve to the grommet can be sealed, for example by inclusion of an O-ring between surfaces of the grommet and the check valve.

The grommet is joined to a purge module body at 1004. The grommet can be joined to the purge module body after or during the joining of the check valve to the grommet at 1002. The grommet can be joined to the purge module body at 1004 by inserting the grommet into a cavity formed in the purge module body and forming a press-fit between an inner wall of the purge module body and an outer wall of the grommet. In an embodiment, the purge module body and/or the grommet can include one or more engagement features to secure the attachment of the purge module body to the check valve, such as, for example, corresponding annular ribs and grooves formed in the purge module body and the grommet, respectively.

A filter is positioned at 1006. The filter can be positioned at 1006 so as to cover passages through the purge module body, such that purge gas flowing through such passages is directed to the filter. In an embodiment, the filter is circular in shape. In an embodiment, the filter includes an opening, for example at a center of the filter. In an embodiment, the purge module body includes a projection, and the filter is positioned at 1006 such that the projection of the purge module body protrudes through the opening in the filter. A filter retainer is attached to the purge module body at 1008. The filter retainer can be attached to the purge module by forming a snap-fit between the filter retainer and the purge module body. In an embodiment, the features forming the snap-fit are provided around an entire perimeter of the purge module, for example an annular projection on the purge module body and a corresponding annular groove on the filter retainer. The attachment of the filter retainer to the purge module body at 1008 can include clamping the filter at a perimeter thereof. In an embodiment where the filter includes an opening, both an outer perimeter of the filter and the inner perimeter of the filter defining the opening can each be clamped by corresponding features of the purge module body and the filter module retainer, such as the features described above and shown in FIGS. 9A and 9B. In an embodiment, the clamping of the filter can be such that the edges of the filter are sealed, minimizing or eliminating escape of the purge gas through sides of the filter.

A diffuser retainer is attached to the filter retainer at 1010. The diffuser retainer includes a diffuser inlet. The diffuser retainer can be attached to the filter retainer at 1010 by, for example, a snap-fit between corresponding engagement features provided on the diffuser retainer and/or the filter retainer. The diffuser retainer can be configured to support a diffuser. The diffuser retainer can include a diffuser inlet. In an embodiment, the method 1000 can further include attaching the diffuser to the diffuser retainer at 1012. In an embodiment, attaching the diffuser includes positioning the diffuser such that it is captured by the diffuser retainer, for example by positioning the diffuser such that a flared portion of the diffuser is surrounded by the diffuser inlet. In an embodiment, the attachment of the diffuser to the diffuser retainer at 1012 can include inserting the diffuser into the diffuser inlet until the diffuser is fully seated in the diffuser inlet.

In an embodiment, the purge module and the diffuser can be installed into a substrate container. Optionally, installation of the diffuser can include inserting the diffuser through an aperture on a substrate container 1014. The insertion of the diffuser into the aperture at 1014 can be performed from an exterior of the substrate container. In an embodiment, installation of the diffuser can include inserting at least a portion of the purge module into the aperture at 1016. and/or attaching the purge module to the substrate container using a module retainer at 1018.

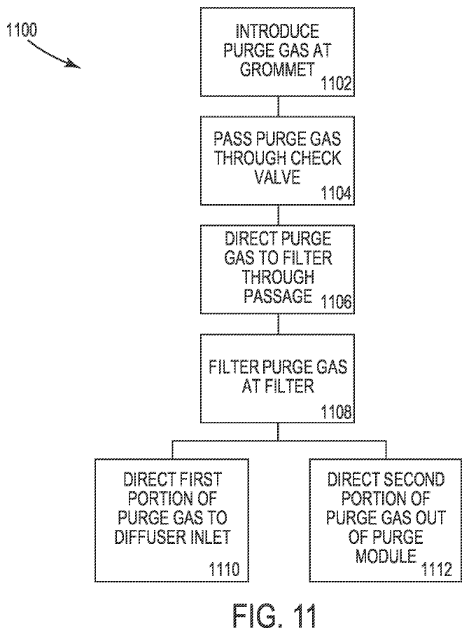

FIG. 11 shows a flowchart of a method of flowing purge gas through the purge module according to an embodiment. Method 1100 includes introducing the purge gas at a grommet at 1102, passing the purge gas through a check valve at 1104, directing the purge gas to a filter by way of a passage in a purge module body at 1106, filtering the purge gas at 1108, directing a first portion of the filtered purge gas to a diffuser inlet 1110 and directing a second portion of the filtered purge gas out of the purge module at 1112.

Purge gas is introduced at the grommet at 1102. The grommet 1102 can interface with a purge source such as a purge gas port provided on a tool that is used with the substrate container including the purge module. The purge gas can be provided at any suitable flow rate for the purging operation. In an embodiment, a flow rate of the purge gas can be controlled to reduce or avoid vibration or lifting of the substrate container. In an embodiment, a flow rate of the purge gas can be in a range from one (1) to 400 standard liters per minute. In an embodiment, the flow rate of the purge gas can be in a range from 200 to 400 standard liters per minute. The purge gas from the grommet passes through a check valve at 1104. The check valve allows one-way flow of the purge gas from the grommet into a chamber defined by the purge module body. The purge gas passes through one or more passages formed in the purge module body to pass from the chamber to a filter provided in the purge module at 1106. The purge gas at the filter is filtered by passing through the filter at 1108. The filtering at 1108 can remove any suitable contaminants such as volatile organic compounds, particulate matter, and the like, based on the structure and composition of the media used in the filter.

A first portion of the purge gas filtered at 1108 is directed to a diffuser inlet at 1110. The first portion of purge gas can include some, but not all of the purge gas that has been filtered at 1108. The direction of purge gas to the diffuser inlet can be directed by structural features of the purge module, such as the shape of a filter retainer, the shape of a diffuser retainer, and/or the position of the diffuser inlet. The purge gas entering the diffuser inlet can then pass into a diffuser, and pass through the diffuser into the substrate container to purge the substrate container.

A second portion of the purge gas filtered at 1108 is directed out of the purge module at 1112. The second portion of the purge gas can be some, but not all of the purge gas passing through the filter at 1108, and different from the first portion that enters the diffuser inlet at 1110. The second portion of the purge gas can exit the purge module at 1112 by way of openings provided in one or both of the filter retainer and the diffuser retainer, without passing into the diffuser inlet. In an embodiment, the second portion of the purge gas enters a chamber defined by the substrate container, for example being defined by one or both of a shell and a bottom plate. In an embodiment, the second portion of the purge gas can further be directed to a second diffuser. In an embodiment, at least some of the purge gas from the chamber can circulate in the chamber and subsequently pass into the diffuser inlet. In an embodiment, relative amounts of the first portion of the purge gas and the second portion of the purge gas can be affected by the pressure within the diffuser and/or the chamber.

### ASPECTS

It is understood that any of aspects 1-9 can be combined with any of aspects 10-31, 32-41, 42-44, 45-51, 52-61, 62-71, or 72-76. It is understood that any of aspects 10-31 can be combined with any of aspects 32-41, 42-44, 45-51, 52-61, 62-71, or 72-76. It is understood that any of aspects 32-41 can be combined with any of aspects 42-44, 45-51, 52-61, 62-71, or 72-76. It is understood that any of aspects 42-44 can be combined with any of aspects 45-51, 52-61, 62-71, or 72-76. It is understood that any of aspects 45-51 can be combined with any of aspects 52-61, 62-71, or 72-76. It is understood that any of aspects 52-61 can be combined with any of aspects 62-71 or 72-76. It is understood that any of aspects 62-71 can be combined with any of aspects 72-76.

Aspect 1. A method of distributing flow of purge gas into a substrate container, comprising: receiving a stream of purge gas at an inlet of a purge module; supplying the purge gas from an outlet of the purge module into a chamber formed by a combination of the purge module and a gas distributor of a purge gas assembly, the gas distributor having at least one outlet; and dividing, in the chamber, the purge gas into at least a first flow path to supply the purge gas to the at least one outlet of the gas distributor.

Aspect 2. The method of aspect 1, wherein the dividing the purge gas further includes supplying the at least first flow path to supply a first gas distributing device and dividing the purge gas into a second flow path to supply a second gas distributing device through a second outlet of the gas distributor.

Aspect 3. The method of aspect 2, wherein the supplying the stream of purge gas includes one or more of: directing the purge gas through a check valve of the purge module into a passageway defined in a module body of the purge module; directing the purge gas from the passageway to a filter through one or more passages in the module body; directing a first portion of the purge gas from the filter and a filter retainer into the first flow path to a first gas distributing device; and directing a second portion of the purge gas from the filter and the filter retainer through one or more apertures defined by one or both of the filter retainer and a diffuser retainer out of the purge module into the second flow path to the second gas distributing device.

Aspect 4. The method of any of aspects 2-3, wherein the dividing in the chamber the purge gas further comprises regulating a flow of the purge gas in the second flow path to the second gas distributing device.

Aspect 5. The method of aspect 4, wherein the regulating the flow of purge gas includes controlling a valve to distribute the flow of the purge gas through the second flow path to the second gas distributing device.

Aspect 6. The method of any of aspects 2-5, wherein the second flow path is formed by connecting a control valve to the second opening of the chamber.

Aspect 7. The method of aspect 6, wherein the connecting of the control valve includes snap-fit connecting a valve body of the control valve to the second opening of the chamber.

Aspect 8. The method of any of aspects 2-7, wherein the second flow path is formed by connecting a tubing or fitting to the second opening in the chamber.

Aspect 9. The method of aspect 8, wherein the connecting of the tubing or fitting includes snap-fit connecting the tubing or fitting to the second opening of the chamber.

Aspect 10. A purge gas assembly for supplying purge gas to a substrate container, the purge gas assembly comprising: a gas distributor comprising at least one outlet; a purge module comprising an inlet for receiving a flow of the purge gas, a check valve, and an outlet; wherein a combination of the gas distributor and the purge module form a chamber, and the chamber is configured to supply the purge gas to the at least one outlet of the gas distributor.

Aspect 11. The purge gas assembly of aspect 10, wherein the gas distributor comprises at least two outlets.

Aspect 12. The purge gas assembly of aspect 11, wherein one of the at least two outlets defines a first opening for directing a first flow path to a first gas distributing device for distributing a first portion of the purge gas in a first portion of the substrate container and one of the at least two outlets defines a second opening for directing a second flow path to at least one second gas distributing device for distributing a second portion of the purge gas to a second portion of the substrate container.

Aspect 13. The purge gas assembly of any of aspects 10-12, wherein the chamber surrounds at least an outlet of the purge module.

Aspect 14. The purge gas assembly of any of aspects 10-13, wherein the purge module further comprises a filter for supplying a filtered purge gas to the outlet of the purge module.

Aspect 15. The purge gas assembly of any of aspects 12-14, wherein the outlet of the purge module comprises at least one of: one or more apertures for supplying the purge gas from the purge module into the chamber or the outlet being at least partially connected to the first gas distributing device.

Aspect 16. The purge gas assembly of any of aspects 12-15, further comprising a control valve connected to the second opening of the chamber for regulating the flow of the purge gas through the second flow path to the second gas distributing device.

Aspect 17. The purge gas assembly of aspect 16, wherein the control valve is a needle valve, ball valve, fixed orifice or butterfly valve.

Aspect 18. The purge gas assembly of any of aspects 16-17, wherein the control valve includes a valve retainer and sealing ring for snap-fit connecting the control valve to the chamber.

Aspect 19. The purge gas assembly of any of aspects 16-18, wherein the control valve includes a security device for preventing changes to valve settings of the control valve.

Aspect 20. The purge gas assembly of any of aspects 12-19, further comprising tubing for forming the second flow path to connect the flow of the purge gas from the chamber to the second gas distributing device.

Aspect 21. The purge gas assembly of aspect 20, wherein the tubing comprises a sealing ring and tube retainer for snap-fit connecting the tubing to the second gas distributing device.

Aspect 22. The purge gas assembly of any of aspects 10-15, further comprising a control valve, tubing, and a carrier plate, wherein the purge module, the control valve, and the tubing are connected along a top surface of the carrier plate.

Aspect 23. The purge gas assembly of any of aspects 10-22, wherein an upper surface of the chamber is formed by a chamber body, a portion of the bottom plate, or along a bottom wall of the substrate container.

Aspect 24. A method for assembling a substrate container having a gas distributing device comprising: attaching a purge gas assembly to a bottom wall of the substrate container, wherein the purge gas assembly comprises a gas distributor comprising at least one outlet; assembling a purge module comprising an inlet for receiving a flow of purge gas, a check valve, and an outlet; inserting the purge module into the gas distributor to form a chamber such that the chamber is configured to supply the purge gas to the at least one outlet, wherein the method is performed externally of the substrate container.

Aspect 25. The method of aspect 24, further comprising attaching a first gas distributing device to the purge module, wherein the attaching of the purge gas assembly includes attaching a second purge gas assembly to the bottom wall of the substrate, wherein the second purge gas assembly comprises a second gas distributor comprising at least one outlet; wherein the inserting the purge module includes inserting a second purge module having a second gas distributing device into the second gas distributor to form a second chamber that surrounds at least the outlet of the purge module such that the second gas distributing device is inserted into the interior space of the substrate container through the at least one outlet of the second gas distributor.

Aspect 26. The method of any of aspects 24-25, wherein the gas distributor comprises at least two outlets.

Aspect 27. The method of aspect 28, wherein attaching the purge gas assembly comprises attaching tubing to connect a second of the at least two outlets of the gas distributor to a second gas distributing device.

Aspect 28. The method of aspect 27, wherein the attaching the tubing comprises snap-fitting a snap-fit connection on the tubing and the second of the at least two outlets of the gas distributor or snap-fitting a snap-fit connection on the tubing and the second gas distributing device.

Aspect 29. The method of any of aspects 26-29, wherein attaching the purge gas assembly comprise attaching a control valve to a second of the at least two outlets of the gas distributor for distributing the flow of purge gas.

Aspect 30. The method of aspect 29, wherein the attaching the control valve comprises snap-fitting a snap-fit connection on an inlet of the control valve to the second opening of the chamber.

Aspect 31. The method of any of aspects 20-24, wherein attaching the purge gas assembly comprises attaching the purge gas assembly to a carrier plate for connecting to the substrate container.

Aspect 32. A purge module, comprising:
a grommet;
a check valve at least partially received in the grommet;
a module body, the module body including a cavity configured to accommodate the grommet and the check valve, the module body defining one or more passages from the cavity; a filter;
a filter retainer, the filter retainer and the module body being configured to contain the filter; and a diffuser retainer configured to support a diffuser, the diffuser retainer including a diffuser inlet;
wherein the filter retainer and the diffuser retainer are configured such that a first portion of a flow of gas through the filter enters the diffuser inlet and a second portion of the flow of gas through the filter passes through one or more apertures defined by one or both of the filter retainer and the diffuser retainer.

Aspect 33. The purge module according to aspect 32, further comprising the diffuser.

Aspect 34. The purge module of claim according to aspect 33, wherein the diffuser is entirely within a perimeter of the module body in plan view.

Aspect 35. The purge module according to any of aspects 32-34, wherein the module body includes a projection extending from a surface, the surface including an end of at least one of the one or more passages.

Aspect 36. The purge module according to aspect 35, wherein a portion of the cavity is defined by the projection, and a portion of the check valve extends into said portion of the cavity.

Aspect 37. The purge module according to any of aspects 35-36, wherein the filter includes an opening defined by an inner perimeter, the opening configured to receive the projection.

Aspect 38. The purge module according to aspect 37, wherein the filter retainer and the module body are configured such that when the filter retainer and the module body are snap-fit together, the filter retainer and the module body clamp the filter along the entire inner perimeter and along an entire outer perimeter of the filter.

Aspect 39. The purge module according to any of aspects 32-38 wherein the module body includes a groove provided on an outer surface of the module body, and the purge module further comprises a circular sealing member disposed in said groove.

Aspect 40. The purge module according to any of aspects 32-39, further comprising a module retainer, the module retainer configured to engage with one or more features of a substrate container.

Aspect 41. The purge module according to any of aspects 32-40, wherein the module body and the filter retainer are configured to be joined by a snap-fit.

Aspect 42. A method of directing purge gas into a substrate container, comprising:
receiving the purge gas at a grommet of a purge module;
directing the purge gas through a check valve into a cavity defined in a module body of the purge module;
directing the purge gas from the cavity to a filter through one or more passages in the module body;
directing a first portion of the purge gas from the filter into a diffuser, the diffuser retained in a diffuser retainer included in the purge module; and directing a second portion of the purge gas out of the purge module through one or more apertures defined by one or both of a filter retainer and the diffuser retainer.

Aspect 43. The method according to aspect 43, wherein the second portion of the purge gas is directed into a chamber surrounding the purge module, the method further comprising directing the second portion of the purge gas from the chamber to a second diffuser.

Aspect 44. The method according to any of aspects 42-43, wherein a flow rate of the purge gas received at the grommet is in a range from 400 standard L/minute or less.

Aspect 45. A method comprising assembling a purge module, wherein assembling the purge module includes:
attaching a check valve to a grommet;
inserting the grommet into a module body;
clamping a filter between the module body and a filter retainer; and
attaching a diffuser retainer to the filter retainer, wherein the diffuser retainer includes a diffuser inlet.

Aspect 46. The method according to aspect 45, wherein the filter retainer and the diffuser retainer are configured such that a first portion of a flow of gas through the filter enters the diffuser inlet and a second portion of the flow of gas through the filter passes through one or more apertures defined by one or both of the filter retainer and the diffuser retainer.

Aspect 47. The method according to any of aspects 45-46, further comprising attaching a diffuser to the diffuser retainer.

Aspect 48. The method according to aspect 47, further comprising inserting the diffuser through an aperture provided on a substrate container from an exterior of the substrate container and inserting the purge module into the aperture such that at least a portion of the purge module is received within the aperture.

Aspect 49. The method according to aspect 48, wherein the aperture is formed by a shell and a bottom plate of the substrate container.

Aspect 50. The method according to any of aspects 39-43, further comprising attaching a locking ring to the module body such that the locking ring can be rotated independently of the module body.

Aspect 51. The method according to aspect 44, further comprising inserting the purge module into an aperture provided on the substrate container from an exterior of the substrate container such that at least a portion of the purge module is received within the aperture, and rotating the locking ring such that the locking ring engages one or more engagement features provided at the aperture.

Aspect 52. A purge module, comprising:
a grommet;
a check valve at least partially received in the grommet;
a module body, the module body including a cavity configured to accommodate the grommet and the check valve, the module body defining one or more passages from the cavity;
a filter;
a filter retainer, the filter retainer and the module body being configured to contain the filter,
wherein the module body includes a projection extending from a surface, the surface including an end of at least one of the one or more passages, and
the filter includes an opening defined by an inner perimeter, the opening configured to receive the projection.

Aspect 53. The purge module according to aspect 52, wherein a portion of the cavity is defined by the projection, and a portion of the check valve extends into said portion of the cavity.

Aspect 54. The purge module according to any of aspects 52-53, wherein the filter retainer and the module body are configured such that when the filter retainer and the module body are snap-fit together, the filter retainer and the module body clamp the filter along the entire inner perimeter and along an entire outer perimeter of the filter.

Aspect 55. The purge module according to any of aspects 52-54, further comprising a diffuser retainer configured to support a diffuser, the diffuser retainer including a diffuser inlet.

Aspect 56. The purge module according to aspect 55, wherein the filter retainer and the diffuser retainer are configured such that a first portion of a flow of gas through the filter enters the diffuser inlet and a second portion of the flow of gas through the filter passes through one or more apertures defined by one or both of the filter retainer and the diffuser retainer.

Aspect 57. The purge module according to any of aspects 55-56, further comprising the diffuser.

Aspect 58. The purge module according to aspect 57, wherein the diffuser is entirely within a perimeter of the module body in plan view.

Aspect 59. The purge module according to any of aspects 52-58, wherein the module body includes a groove provided on an outer surface of the module body, and the purge module further comprises a lip seal disposed in said groove.

Aspect 60. The purge module according to any of aspects 52-59, further comprising a module retainer, the module retainer configured to engage with one or more features of a substrate container.

Aspect 61. The purge module according to any of aspects 52-60, wherein the module body and the filter retainer are configured to be joined by a snap-fit.

Aspect 62. A method comprising assembling a purge module, wherein assembling the purge module includes:
attaching a check valve to a grommet;
inserting the grommet into a module body, wherein the module body includes a surface having a projection;
positioning a filter having an opening such that the projection extends through the opening; attaching a filter retainer to the module body such that the filter retainer and the module body clamp the filter at an outer perimeter of the filter and at an inner perimeter of the filter, the inner perimeter defining the opening.

Aspect 63. The method according to aspect 62, further comprising attaching a diffuser retainer to the filter retainer, wherein the diffuser retainer includes a diffuser inlet.

Aspect 64. The method according to aspect 63, wherein the filter retainer and the diffuser retainer are configured such that a first portion of a flow of gas through the filter enters the diffuser inlet and a second portion of the flow of gas through the filter passes through one or more apertures defined by one or both of the filter retainer and the diffuser retainer.

Aspect 65. The method according to any of aspects 63-64, further comprising attaching the diffuser to the diffuser retainer.

Aspect 66. The method according to aspect 65, further comprising inserting the diffuser through an aperture provided on a substrate container from an exterior of the substrate container and inserting the purge module into the aperture such that at least a portion of the purge module is received within the aperture.

Aspect 67. The method according to any of aspects 62-67, further comprising attaching a locking ring to the module body such that the locking ring can be rotated independently of the module body.

Aspect 68. The method according to aspect 67, further comprising inserting the purge module into an aperture provided on a substrate container from an exterior of the substrate container such that at least a portion of the purge module is received within the aperture, and rotating the locking ring such that the locking ring engages one or more engagement features provided at the aperture.

Aspect 69. The method according to any of aspects 62-68, wherein the filter retainer and the module body clamp the filter over an entirety of the outer perimeter of the filter and over an entirety of the inner perimeter of the filter.

Aspect 70. The method according to any of aspects 62-69, wherein the filter retainer and the module body are joined by a snap-fit.

Aspect 71. The method according to any of aspect 62-70, wherein the module body defines a cavity, a portion of the cavity is defined by the projection, and a portion of the check valve extends into said portion of the cavity.

Aspect 72. A purge assembly for a substrate container, comprising:
a housing; and
a purge module, the housing and the purge module defining a chamber, the purge module comprising:
a grommet;
a check valve at least partially received in the grommet;
a module body, the module body including a cavity configured to accommodate the grommet and the check valve, the module body defining one or more passages from the cavity;
a filter; and
a filter retainer, the filter retainer and the module body being configured to contain the filter,
   wherein the purge module is configured to receive a flow of purge gas, direct the flow of purge gas through the check valve to the filter, and allow at least a portion of the flow of purge gas to pass from the purge module into the chamber.

Aspect 73. The purge assembly according to aspect 72, further comprising a diffuser configured to extend from the housing.

Aspect 74. The purge assembly according to aspect 73, wherein the diffuser is retained in the housing.

Aspect 75. The purge assembly according to aspect 74, wherein the purge module contacts the diffuser such that the diffuser is retained in an aperture provided in the housing.

Aspect 76. The purge assembly according to aspect 73, wherein the purge module further includes a diffuser retainer further configured to support the diffuser.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A method of distributing flow of purge gas into a substrate container, comprising:
receiving a stream of purge gas at an inlet of a purge module;
supplying the purge gas from an outlet of the purge module into a chamber formed by a combination of the purge module and a gas distributor of a purge gas assembly, the gas distributor having at least one outlet; and
dividing, in the chamber, the purge gas into at least a first flow path to supply the purge gas to the at least one outlet of the gas distributor.

2. The method of claim 1, wherein the dividing the purge gas further includes supplying the at least first flow path to supply a first gas distributing device and dividing the purge gas into a second flow path to supply a second gas distributing device through a second outlet of the gas distributor.

3. The method of claim 2, wherein the supplying the stream of purge gas includes one or more of:
directing the purge gas through a check valve of the purge module into a passageway defined in a module body of the purge module;
directing the purge gas from the passageway to a filter through one or more passages in the module body;
directing a first portion of the purge gas from the filter and a filter retainer into the first flow path to a first gas distributing device; and
directing a second portion of the purge gas from the filter and the filter retainer through one or more apertures defined by one or both of the filter retainer and a diffuser retainer out of the purge module into the second flow path to the second gas distributing device.

4. The method of claim 2, wherein the dividing in the chamber the purge gas further comprises regulating a flow of the purge gas in the second flow path to the second gas distributing device.

5. The method of claim 4, wherein the regulating the flow of purge gas includes controlling a valve to distribute the flow of the purge gas through the second flow path to the second gas distributing device.

6. The method of claim 2, wherein the second flow path is formed by connecting a control valve to the second opening of the chamber.

7. The method of claim 6, wherein the connecting of the control valve includes snap-fit connecting a valve body of the control valve to the second opening of the chamber.

8. The method of claim 2, wherein the second flow path is formed by connecting a tubing or fitting to the second opening in the chamber.

9. A purge gas assembly for supplying purge gas to a substrate container, the purge gas assembly comprising:
a gas distributor comprising at least one outlet;
a purge module comprising an inlet for receiving a flow of the purge gas, a check valve, and an outlet;
wherein a combination of the gas distributor and the purge module form a chamber, and
the chamber is configured to supply the purge gas to the at least one outlet of the gas distributor.

10. The purge gas assembly of claim 9, wherein the gas distributor comprises at least two outlets.

11. The purge gas assembly of claim 10, wherein one of the at least two outlets defines a first opening for directing a first flow path to a first gas distributing device for distributing a first portion of the purge gas in a first portion of the substrate container and one of the at least two outlets defines a second opening for directing a second flow path to at least one second gas distributing device for distributing a second portion of the purge gas to a second portion of the substrate container.

12. The purge gas assembly of claim 9, wherein the chamber surrounds at least an outlet of the purge module.

13. The purge gas assembly of claim 9, wherein the purge module further comprises a filter for supplying a filtered purge gas to the outlet of the purge module.

14. The purge gas assembly of claim 11, wherein the outlet of the purge module comprises at least one of: one or more apertures for supplying the purge gas from the purge module into the chamber or the outlet being at least partially connected to the first gas distributing device.

15. The purge gas assembly of claim 11, further comprising a control valve connected to the second opening of the chamber for regulating the flow of the purge gas through the second flow path to the second gas distributing device.

16. The purge gas assembly of claim 15, wherein the control valve is a needle valve, ball valve, fixed orifice or butterfly valve.

17. The purge gas assembly of claim 15, wherein the control valve includes a valve retainer and sealing ring for snap-fit connecting the control valve to the chamber.

18. The purge gas assembly of claim 15, wherein the control valve includes a security device for preventing changes to valve settings of the control valve.

19. The purge gas assembly of claim 9, wherein an upper surface of the chamber is formed by a chamber body, a portion of the bottom plate, or along a bottom wall of the substrate container.

20. A method for assembling a substrate container having a gas distributing device comprising:
attaching a purge gas assembly to a bottom wall of the substrate container, wherein the purge gas assembly comprises a gas distributor comprising at least one outlet;
assembling a purge module comprising an inlet for receiving a flow of purge gas, a check valve, and an outlet;
inserting the purge module into the gas distributor to form a chamber such that the chamber is configured to supply the purge gas to the at least one outlet, wherein the method is performed externally of the substrate container.
